(19) United States
(12) Patent Application Publication
(10) Pub. No.: US 2009/0164124 A1
(43) Pub. Date: Jun. 25, 2009

(54) ULTRA WIDEBAND RECEIVER FOR LIGHTNING DETECTION

(75) Inventors: Dean E. Ryan, Dublin, OH (US); Matthew A. Gessner, Delaware, OH (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Advidyne Corporation, Lincoln, MA (US)

(21) Appl. No.: 11/963,184

(22) Filed: Dec. 21, 2007

(51) Int. Cl. G01R 29/08

(52) U.S. Cl. 702/4

(57) ABSTRACT

The present invention relates to a system and method for detecting lightning activity. When a lightning strike is close enough to a receiver, the strength of the signal received will cause the receiver to saturate. In such a situation, a non-filtered signal is used to calculate a range and bearing. In one specific embodiment, a receiver detects energy emitted by a lightning strike and separates the lightning strike to a filtered signal and non-filtered signal. A saturation detector determines if the filtered signal is saturated prior to the filtered signal being filtered. In response to the filtered signal being saturated, a processor processes the non-filtered signal from the receiver, estimates locations of the detected lightning strike relative to the system, determines a cumulative effect of the lightning strike spaced in distance and time, and generates display signals to illustrate the cumulative effect with respect to a grid.

### RELATED APPLICATIONS

This application is related to U.S. application Ser. No. 11/488,792, entitled “Method and Apparatus for Detecting and Processing Lightning”, filed on Jul. 19, 2006, which claims the benefit of the filing date of co-pending provisional application Ser. No. 60/700,334, filed on Jul. 19, 2005. The entire teachings of the above applications are incorporated herein by reference.

### BACKGROUND

Electrical storms pose a host of problems for aircraft pilots. For example, lightning can wreak havoc on in-flight electronics and instrumentation. Of greater concern, however, is the air turbulence that always accompanies electrical storms. The strength of this turbulence makes it dangerous for aircraft, particularly small aircraft, to fly through electrical storms.

Equipment therefore has been developed which enables pilots to detect, and thus avoid, electrical storms during flight. This equipment typically includes a detector for detecting electrical activity of nearby storms, and a monitor for displaying lightning strikes (meaning any electrical discharge) occurring in these so-called storm cells. Current lightning strikes are typically depicted on the monitor as an “x” or a “+”, which remains displayed for an amount of time, after which the “x” or “+” is removed.

Lightning displays, such as those described above, make it difficult for pilots to interpret the information that they are receiving. For example, it is difficult to determine the spatial density of lightning in a particular area using such a display. It is also difficult to determine storm trend information, such as whether a storm is increasing or decreasing in intensity.

Over the past 25 years, the aviation industry has been the beneficiary of improved storm mapping systems. See U.S. Pat. Nos. 4,023,408; 4,395,906; and 6,347,549. Those storm mapping systems took advantage of the correlation between thunderstorms and lightning discharges. The violent air currents that are hazardous to aircraft flight produce the lightning discharge. The lightning discharge also generates electromagnetic waves. Directional receiving apparatus located on board an aircraft can determine the direction of the lightning discharge. Some information is available about the distance or range of the discharge as well. By receiving and storing this direction and distance information, a map is formed from the stored data, to give the pilot a plan view image of the storm activity relative to the aircraft. Notwithstanding the wide utility of aircraft carried storm mapping systems there is room for significant improvement.

Because of the limited area of the display it is necessary to pick and chose just what information to display and how to display it so as to convey to the user the most important information within the limits of the display. A solution to this desire should not be too rigid but instead allow the user to configure the display parameters to meet the current needs of the user.

In addition there is a need to provide for improved signal processing in respect of at least two different problems.

While lightning is a robust radiator of electromagnetic radiation, the environment in which these instruments are used is subject to a wide variety of noise sources, including sources located on the very same vehicle as is the storm mapping system. Earlier devices have attempted to accept signals generated by lightning while excluding signals derived from noise sources. There is room for much improvement in this area.

Even if the devices succeed in excluding all unwanted signals, there is still the problem of extracting the information which will accurately locate the lightning. For example, ranging to close-in lightning is a substantial problem if the instrument must also be able to work at reasonable ranges, say significantly greater than 100 nautical miles. There is room for significant improvements in this area as well.

Sometimes it is desirable to filter noise based on the wave shape of the received signals. However, in an effort to minimize noise, the filtering process may make it more difficult to properly detect the waveform of lightning. In order to be effective, this requires that the data collection be capable of preserving information descriptive of the wave shape. To this end, the data that the apparatus collects is capable of describing peaks in the waveforms and relating peaks in three different channels to each other. This allows the system to obtain a measure of correlation between the loops signals and the sense signals. As will be further described, the system requires the waveforms to be correlated within specific limits before the signals will be accepted as originating with lightning.

### SUMMARY OF THE INVENTION

A method and corresponding system for detecting lightning activity is provided and addresses problems of the prior art. In one embodiment, the system includes a receiver to detect energy emitted by a lightning strike. The receiver separates the detected indication of a lightning strike into a filtered signal and a non-filtered signal. The system further includes a saturation detector to determine if the filtered signal is saturated prior to the filtered signal being filtered. In response to the filtered signal being saturated, a processor processes the non-filtered signal from the receiver, estimates locations of the detected lightning strike relative to the system, determines a cumulative effect of the at least one lightning strike spaced in distance and time, and generates display signals to illustrate the cumulative effect with respect to a grid.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating example embodiments of the invention.

FIG. 1A is a block diagram of a system for detecting lightning activity employing example embodiments of the invention;

FIG. 1B is a more detailed block diagram of a receiver in accordance with example embodiments of the invention;

FIG. 1C is a functional block diagram illustrating the functions performed by the processor complex 105 in accordance with example embodiments of the invention;

FIG. 2 is a flow chart of steps performed by the system to use the filtered signal or the non-filtered signal in accordance with example embodiments of the invention;

FIG. 3 is a more detailed block diagram of one component of the signal processing element in accordance with example embodiments of the invention;

FIGS. 4A-4F are flow diagrams of the logic implemented in the signal processor component of the block diagram in accordance with example embodiments of the invention;

FIG. 5 illustrates a grid format for one type of display in accordance with example embodiments of the invention;

FIG. 6 illustrates a distribution of strikes in a flash in accordance with example embodiments of the invention;

FIG. 7 illustrates a component of a model lightning strike in accordance with example embodiments of the invention;

FIGS. 8A and 8B illustrate images of the combined flash and cell mode display in accordance with example embodiments of the invention;

FIG. 9 illustrates how a range may be calculated from pulse width in accordance with example embodiments of the invention;

FIG. 10 is an illustration of a display mode which allows pertinent weather statistics to be selected by a user for display in accordance with example embodiments of the invention;

FIG. 11 is a flow diagram of functions performed by the programmable processor preparatory to flash processing in accordance with example embodiments of the invention;

FIG. 12 is a diagram illustrating further processes of the programmable processor in accordance with example embodiments of the invention;

FIG. 13 shows waveforms of three signals typical of lightning originated signals which are well correlated in accordance with example embodiments of the invention;

FIG. 14 shows three waveforms having some similarity to the waveforms of FIG. 13 but which are not correlated in accordance with example embodiments of the invention; and

FIG. 15 is a lightning originated waveform which has its range extended by being channeled in accordance with example embodiments of the invention.

### DETAILED DESCRIPTION OF THE INVENTION

A description of preferred embodiments of the invention follows.

Although detecting “model” lightning strikes in a perfect clean digital data stream is trivial, it is necessary to be able to identify and reject various noise sources that may have an appearance similar to lightning, and to accurately and consistently identify “real” lighting in the presence of an imperfect or noisy input data stream. When a lighting strike is close enough to a receiver, the strength of the signal received will cause the receiver to saturate. Although the receiver is designed to handle the amplitude of signals received from very close lightning strikes, there is no way to measure the peak amplitude once the receiver output is saturated. When this happens, the amplitude of the strike is measured at the Width Trigger Level (WTL). The WTL is set at a level below saturation, since the width at the saturation level will not change much until well after saturation has occurred. To this end, typically a lighting strike signal is filtered, rejecting signals which do not fit the format of lightning and/or minimize noise. The filtered signal is then used to generate a waveform for measuring the WTL. However, the use of filters make it more difficult to properly measure the waveform of the lightning strike. Specifically, it is difficult to accurately measure the width of the lightning waveform. Furthermore, as the lightning strike gets closer to the receiver, it is more difficult to obtain a waveform of the lightning strike because the output of the receiver is related to the amplitude of the received signal. Thus, as the lighting strike gets closer to the receiver, the amplitude of the received signal gets higher.

As such, it is desirable to use the non-filtered signal, which is the signal before filtering has taken place, to measure the width of the waveform when the filtered signal has been saturated. In the past, using a non-filtered signal is less than desirable because the non-filtered signal can detect unwanted noise. However, the invention system utilizes the filtered signal to make a decision as to whether or not to use the non-filtered signal. So the system may look at the non-filtered signal to determine how wide the signal is and/or how wide the saturated signal is, but the system does not use other information from the non-filtered signal unless the filtered signal is saturated, and it is that qualification of the non-filtered signal that makes it desirable to use the non-filtered signal. The determination of whether the filtered signal is saturated or not is done prior to the filtered signal going through any filtering process. A signal that is saturated is generally understood as a received signal with a power level that exceeds the dynamic range of the receiver. For such a level, any increase in the power level causes no appreciable change in the output of the receiver.

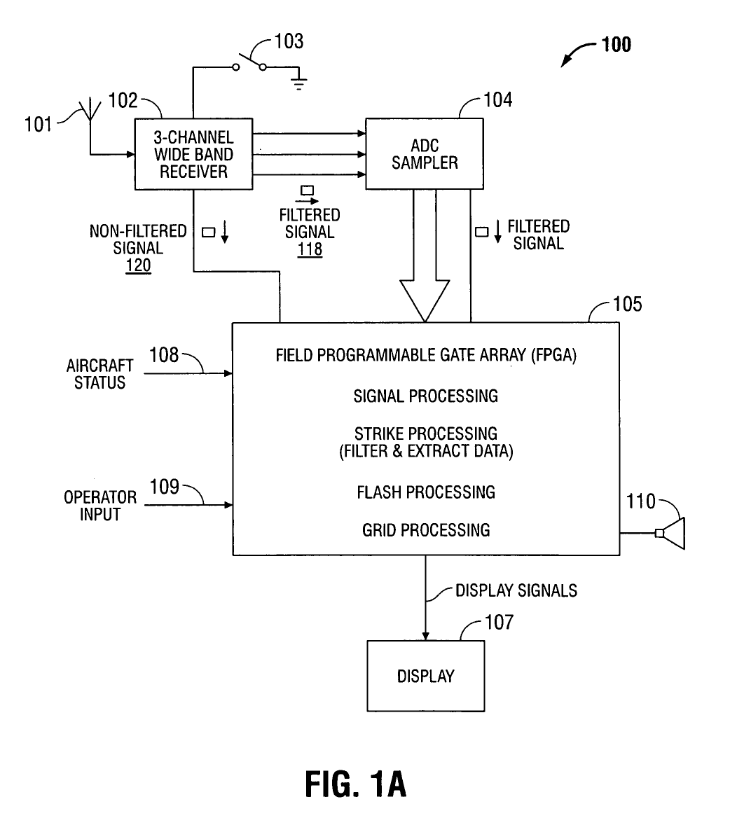

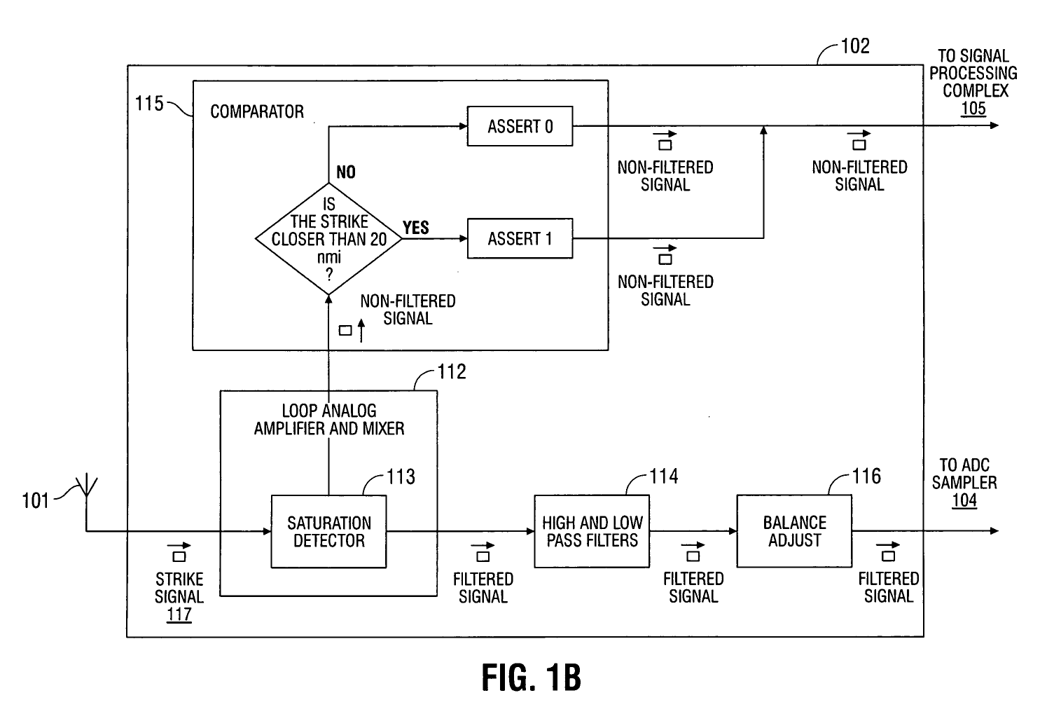

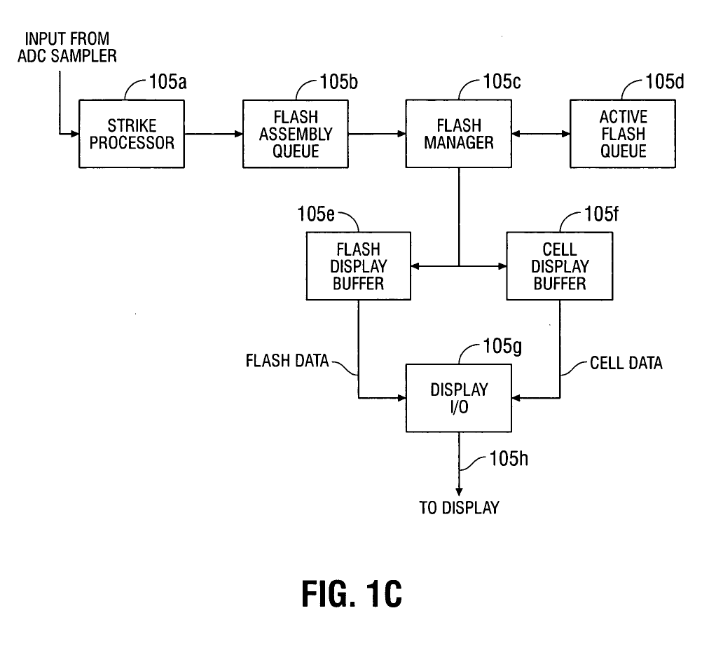

FIG. 1A is a block diagram of a system 100 for detecting lightning activity. As is well known, lightning is a radiator of electromagnetic energy. The antenna complex 101 preferably comprises two directional loop antennas and an omni directional electric field sensor antenna. The loop antennas are preferably oriented orthogonal to each other to sense magnetic field components. The sense antenna is omni directional and senses the electric field components. Inputs from the antenna complex 101 are provided through a three-channel wide band receiver/amplifier 102. In the past, many receivers for lightning detecting equipment include a relatively narrow band receiver. An ultra wide band amplifier of 200 or 300 khz band width is preferably used in order to preserve the waveform of the electro magnetic radiation and rejecting signals which do not fall into the pattern exhibited by lightning. The receiver 102 may detect energy emitted by at least one lightning strike. The receiver may further separate the strike signal 117 generated by the lightning strike to a filtered signal 118 and a non-filtered signal 120.

Outputs of the non-filtered signals 120 may be coupled to the signal processor complex 105, thus bypassing the ADC sampler 104. In response to the filtered signal 118 being saturated, the signal processor complex 105 processes the non-filtered signal 120 from the receiver 102, estimates locations of the detected at least one lightning strike relative to the system 100, determines a cumulative effect of the at least one lightning strike spaced in distance and time, and generates display signals to illustrate the cumulative effect with respect to a predetermined grid.

Outputs of the filtered signals 118 from the three-channel wide-band receiver 102 may be coupled to a sampler or an analog to digital converter 104. The digitized outputs of the converter 104 are provided as an input to a signal processor complex 105. In one embodiment the complex 105 includes a programmable logic device which accepts the sequences of samples generated by the sampler 104, applies a first set of tests to the waveforms depicted by the sequences of samples and, with respect to those waveforms which passed the first set of tests developes a set of waveform parameters and other descriptors of the sequences of samples and passes that information to a host processor which continues the signal processing functions. In one embodiment, the programmable logic device component of the processor complex 105 may be an ALTERA CYCLONE Field Programmable Gate Array (FPGA). Generally, a FPGA is a semiconductor device containing programmable logic components, and programmable interconnects. The programmable logic or “logic blocks” may be programmed to perform the function of basic logic gates such as AND, XOR, or any combination thereof. The FPGA may determine which signal (e.g., filtered signal 118, non-filtered signal 120) to use for reflecting a waveform conforming to a lightning strike and to generate a set of waveform parameters (to be described) for further processing. The further processing includes determining range and bearing to each strike. The FPGA may look at the non-filtered signal 120 to determine how wide the signal is and/or how wide the saturated signal is, but the system 100 does not use information from the non-filtered signal 120 unless the filtered signal 118 is saturated, and it is that qualification of the non-filtered signal 120 that makes it desirable to use the non-filtered signal.

While FIG. 1A shows a display 107, it is within the scope of the invention to manufacture a product comprising the antenna complex 101, receiver 102, ADC sampler 104 and processor complex 105. A user can complete the system 100 by adding any one of many different out devices (e.g., audio, visual or both), such as the display 107 and speaker 110 shown in FIG. 1A.

It will be apparent that a wide variety of signal processors and host computers can be used to implement these functions, all within the scope of the invention.

The A-D converter 104 provides, in its output channels, a regular sequence of regular signal samples, including one for each of the outputs derived from the loop antennas; and an output derived from the sense antenna.

Because of the wide band nature of the amplifier 102 the digital samples preserve the wave form of the fields sensed by the antenna complex 101. That is, the digital samples faithfully represent the amplitude of the electric and magnetic field components produced by the subject lightning.

The signal processor complex 105 includes some simple filtering, rejecting filtered signals 118 which do not fit the format of lightning. In a preferred embodiment, the equipment provides signals to drive a display for a plurality of range scales, the maximum being 200 nautical miles, e.g., lightning originating beyond 200 nm should be rejected.

The signal processor complex 105, when it detects a sequence of signals (filtered signals 118 and/or non-filtered signals 120) reflecting a waveform conforming to a lightning strike generates a set of waveform parameters (to be described) for further processing. The further processing includes determining range and bearing to each strike.

The strike data whether it is from the filtered signal 118 or the non-filtered signal 120, is then passed to a flash assembler 105b (FIG. 1c). A flash assembler is described in U.S. Pat. No. 6,347,549 herein incorporated by reference which, with slight modifications is adequate to generate flash data for use in a preferred embodiment of the invention. Alternatively, those skilled in the art will understand how other and different equipment could also be used. The description of the flash assembler in the '549 patent limits a flash to activity occurring with gaps of not more than 50 ms. However, the preference is to define the duration of a flash as 1000 ms, e.g., one second. The flash assembler then passes data identifying completed flashes for further processing and combines the effect of certain flashes to generate display signals to allow the display, to the user of the cumulative effect of the plurality of lightning strikes. The signal processor complex 105 is also subject to operator input 109 and aircraft status information 108. A result of information input is the generation of display signals for a display 107 or audio signals for a speaker 110 providing information to the user concerning weather related to lightning.

FIG. 1B is a more detailed block diagram of a receiver 102 in accordance with example embodiments of the invention. The receiver 102 may include a loop analog amplifier and mixer 112, high and low pass filters 114, and a balance adjust 116. The loop analog amplifier and mixer 112 may include at least one saturation detector 113 to determine if the strike signal 117 is above some threshold, or in other words, if the strike signal 117 is saturated. The saturation detector 113 is placed before the filters 114 have a chance to alter the strike signal 117. The information that a particular strike signal 117 is saturated is passed onto the FPGA, which may be located within the signal processor 105. The outputs of the saturation detector 113 have two signal paths (filtered signal 118 and non-filtered signal 120) as a result of a lightning strike. The filtered signal 118 may proceed to the high and low pass filters 114 to filter out unwanted noise. The filtered signal 118 may continue to the balance adjust 116. To take advantage of the dynamic range of the ADC sampler 104, the filtered signal may be scaled. For example, if the ADC sampler 104 has a range of 0 to 2 Volts and the filtered signal is 0 to 4 Volts, then the balance adjust 116 may scale the filtered signal 118 to a range of 0 to 2 Volts. By scaling the filtered signal 118, a more accurate representation of an input waveform may be created. The filtered signal then continues to the signal processor 105 as discussed above in FIG. 1A.

The non-filtered signal 120 may proceed to a comparator 115. The comparator determines whether the lightning strike, using the non-filtered signal 120, is closer than, for example, 20 nautical miles (nmi). The comparator 115 then asserts a flag “0” if the strike is greater than 20 nmi or “1” if the strike is less than or equal to 20 nmi. The non-filtered signal 120 then proceeds to the signal processor 105.

At the signal processor 105, the FPGA determines whether it should use the filtered signal or the non-filtered signal for measuring the waveform to determine a range and bearing. The FPGA is always counting the widths of the non-filtered signal 120 or how many flags (output from comparator 115) have a “1”, while monitoring the information that the filtered signal 118 has been saturated as determined by the saturation detector 113. When a lightning strike is complete and all the logic says this is a lightening strike and the filtered signal 118 is saturated, the FPGA uses the non-filtered signal 120 to calculate a range and bearing. In other words, the FPGA uses the non-filtered signal 120 only if the filtered signal 118 is saturated and the non-filtered signal has a flag of “1” to indicate that the lightning strike is equal to or less than 20 nmi. If the filtered signal 118 is not saturated or the non-filtered flag is a “0”, the signal processor 105 will use the filtered signal 118 to determine the range and bearing.

FIG. 1C is a functional block diagram illustrating the functions performed by the processor complex 105 in accordance with example embodiments of the invention. The Strike Processor 105a operates on the input samples from the ADC Sampler 104 (filter signals 118) or the receiver 102 (non-filtered signals 120) to create a data set for selected signal sequences, i.e., those sample sequences which pass the tests imposed to identify lightning originated waveforms falling within the selected range limit. The data set includes range and bearing information as well as polarity and a time mark and perhaps related information as described in the '549 patent. This data set is passed on to the Flash Assembly Queue 105b. As described in the '549 patent the Flash Manager 105c uses the data from the Flash Assembly Queue 105b and data in the Active Flash Queue 105d to form flashes, i.e., concatenate strikes at or near a common bearing and which occur within a predetermined time of each other (in one embodiment within one second). The flash data is then used to write the Flash Display Buffer 105e and the Cell Display Buffer 105f. The Flash Display Buffer 105e is simply a listing of each of the flashes including range, bearing, polarity and weight (the number of strikes) so as to be capable of providing display signals 105h (from display I/O 105g) to any associated display to generate a flash display as will be described.

The data in the cell display buffer 105f is organized in accordance with a predetermined grid of hexagonal elements. Each flash has an effect over a predetermined range, with the effect decreasing with distance from the origin of the flash. The data in the cell display buffer 105f is generated by first summing, for any cell, the total weight of flashes affecting that cell. There is a different cell display buffer for each different range scale within the capability of a display. The data stored in the cell (color index) is an index reflecting the weight calculated for that cell and the particular range scale of the related display.

The signal processor complex 105 also operates an alert speaker 110 based on the data in the flash buffer 105e. In particular, lightning strikes that are extremely close should be called to the attention of the pilot. The system 100, for example, may select 5 nmi as the threshold, i.e., lightning within a 5 nmi range will generate an audible alert unless suppressed. The audible alert announces the presence of lightning as well as the quadrant or more specific bearing data, e.g., “Lightning at One O'clock.” While the audible alert can be helpful, in the case of extreme close-in activity multiple callouts can be an annoyance. Therefore, after the second callout at the same or an adjacent bearing within a predetermined time, the callouts may be suppressed until the expiration of that time. A suitable time, for example, may be 3 minutes. In addition, one of the operator inputs 109 allows the operator to suppress or inhibit audible callouts at will.

In the search for a method of displaying lightning data in a manner that represents regions of activity, the following considerations are important:

The images must be visually appealing and informative.

The lightning images must be distinguishable from typical RADAR images. To avoid confusion, it should be clear to the operator that they are looking at a depiction of lightning data, not RADAR.

Color should be used to depict the relative intensity of the lightning within a region.

The image should de-accentuate non-lightning data, and data that varies from the model such as radial spread.

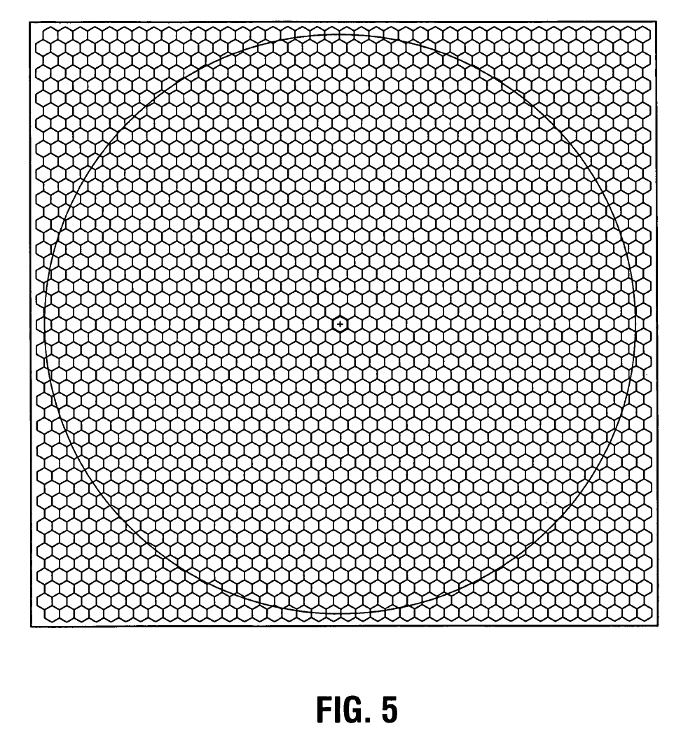

Although some of these considerations appear to be mutually exclusive, a method has been devised that accommodates all of the above goals. This method involves dividing the display region into a hexagonal grid (refer to FIG. 5). Each element of the grid (i.e., a cell) will have an associated weight, which will be used to determine the color with which the element is drawn. The image is then constructed from the hexagonal grid using the following considerations:

A colored hexagon is drawn for each cell, not some other shape.

Colored hexagons are separated by a distinct black hexagonal grid; the colored regions do not touch one another.

The result is an image that is visually distinct and appealing. The black hexagonal grid that separates the hexagons creates a unique appearance that can be readily distinguished from typical RADAR images. The hexagonal grid lightning images are not necessarily overlaid on RADAR images, but it is important that the operator be aware that it is lightning data, not RADAR images, being observed.

By selecting the weight properly (as described below), the higher weights will tend to be where the lightning data clusters. This will tend to de-accentuate non-lightning data such as radial spread. By selecting the colors associated with the lowest weights so that they are somewhat darker and more subdued, the visual presentation will help the operator to focus on the regions of greatest interest. A sample color selection is outlined in Table 1 below.

TABLE 1
Sample color assignments for 8-level weights.

| Index | Color Description | R | G | B |
|---|---|---|---|---|
| 0 | Black | 0.0 | 0.0 | 0.0 |
| | (or invisible) | | | |
| 1 | dark blue-green | 0.0 | 0.3 | 0.8 |
| 2 | dim green | 0.0 | 0.6 | 0.2 |
| 3 | green-yellow | 0.5 | 0.8 | 0.0 |
| 4 | Yellow | 1.0 | 1.0 | 0.0 |
| 5 | orange-yellow | 1.0 | 0.7 | 0.0 |
| 6 | Orange | 1.0 | 0.5 | 0.0 |
| 7 | Red | 1.0 | 0.0 | 0.0 |

The relationship between the weight of a hexagon and the color index used for the hexagon is best described by relying on two parameters. The two parameters include the desired range scale and the weight. The color of the hexagon is obtained from the two parameters. This is useful since each range scale may have a different relationship between weight and color. It has been found that scattered thunderstorm activity displayed at longer range scales can lead to a screen-full of colored hexagons that make it appear that there is an impenetrable mass of activity. To prevent this, and to de-accentuate radial spread, the longer ranges use black for the lowest weights. Color does not show up until the weight is substantial enough to be a clear indication of thunderstorm activity. This helps the pilot to find the true areas of activity without an overwhelming solid mass of color; however, it introduces a concern that light to moderate activity may not be displayed at close ranges. To resolve this concern, an indication is provided to the pilot when viewing the longer range scales that there is activity on the 25 nmi range scale. The usefulness of this approach to minimize radial spread cannot be overstated. This technique of accentuating the more intense centers of activity provides information to the pilot that has previously been unattainable without airborne lightning detection equipment.

The hexagonal depiction of the lightning data may be overlaid with RADAR data by drawing only the grid lines of the hexagonal grid. The center of each hexagon is transparent to allow the radar data to be viewed through the grid. The edges of each hexagon may be drawn in the color associated with its weight and are bordered with black to allow it to be clearly distinguished from the RADAR image behind it. The hexagons are drawn in order of increasing weight so that the highest intensity hexagons appear in front of the lower intensity hexagons.

In practice, the following considerations have been found to be desirable:
Each hexagonal element (or simply each hexagon) should be oriented with a point up as shown in FIG. 5. The vertices of the hexagon should be at 12 o'clock, 2 o'clock, 4 o'clock, 6 o'clock, 8 o'clock, and 10 o'clock with respect to the center of the hexagon.
If the number of rows and columns is odd as preferred, then there is a “center” hex.
The range of the image should be defined as the distance from the center of the first hex in the middle row to the center of the last hex in the middle row. This accommodates the half-hex shift that occurs in the rows immediately above and below the middle row.
Depending on other information shown on the display, the entire grid may be displayed, or the image may be limited to some portion of the grid.

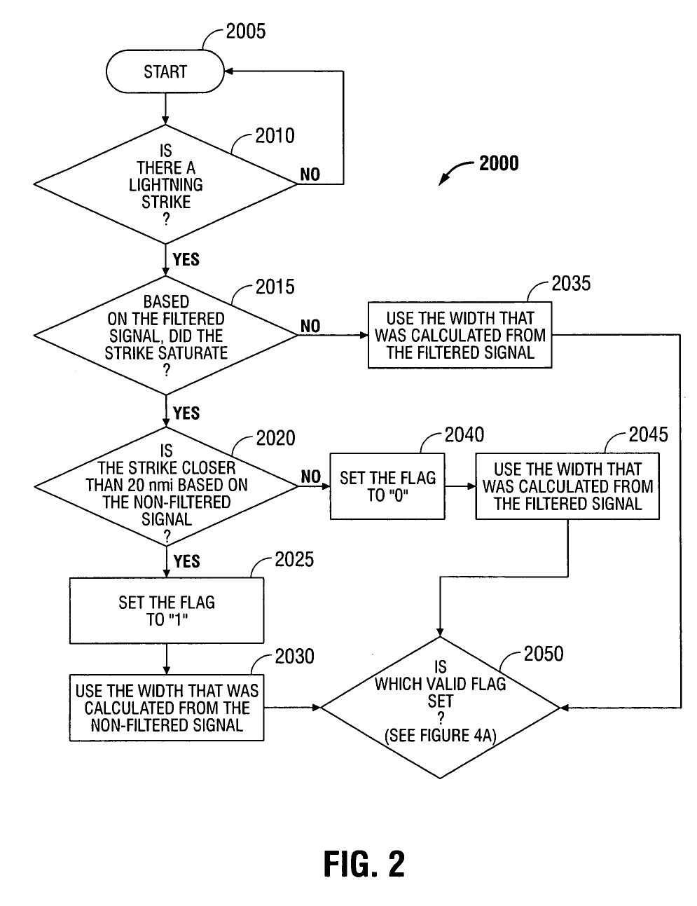

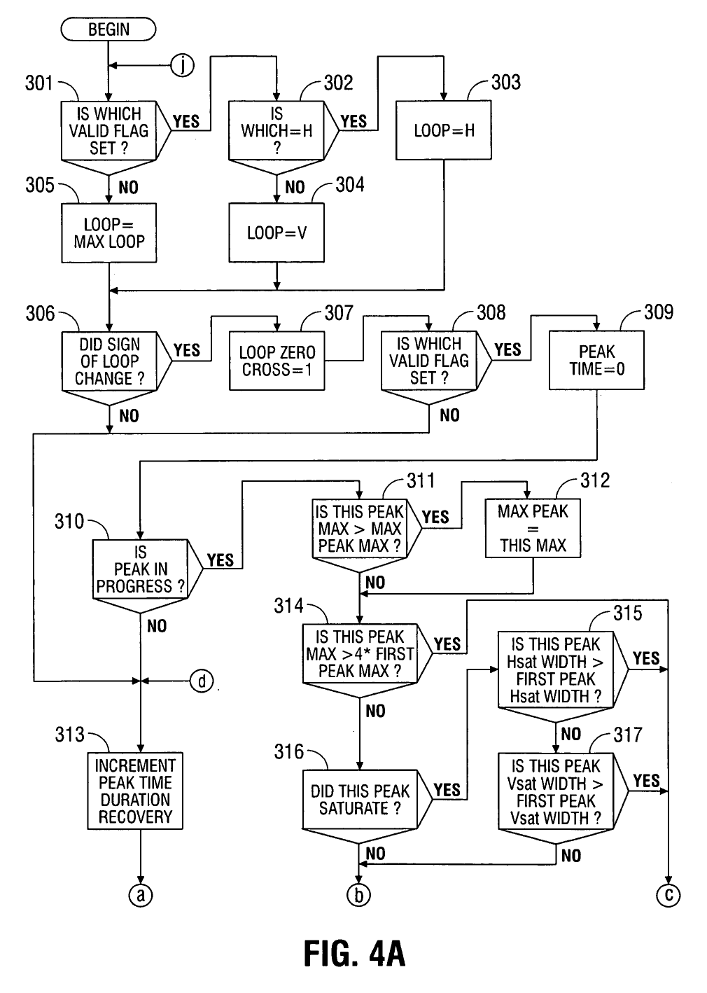

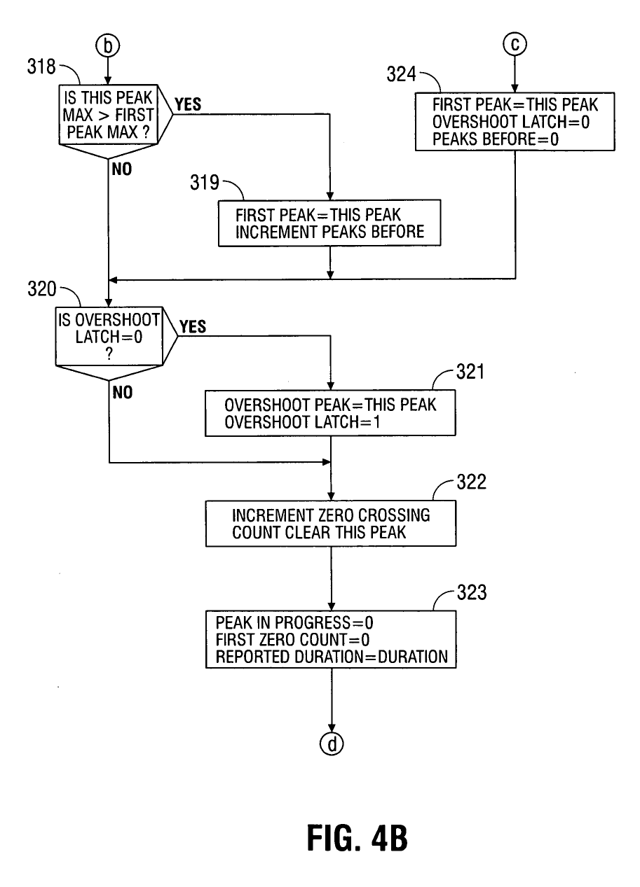

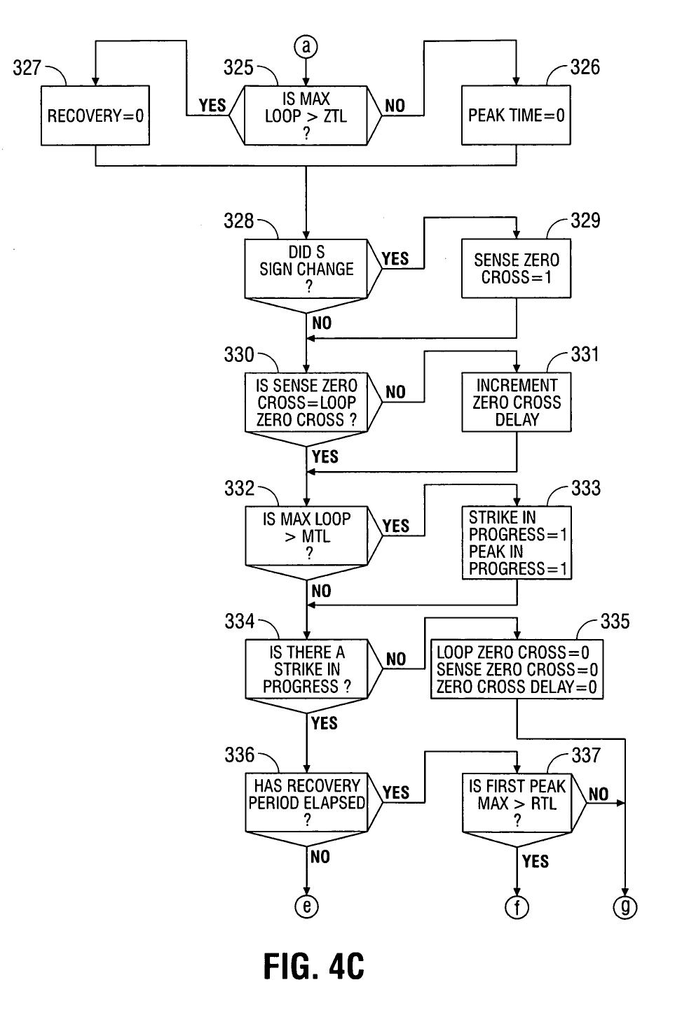

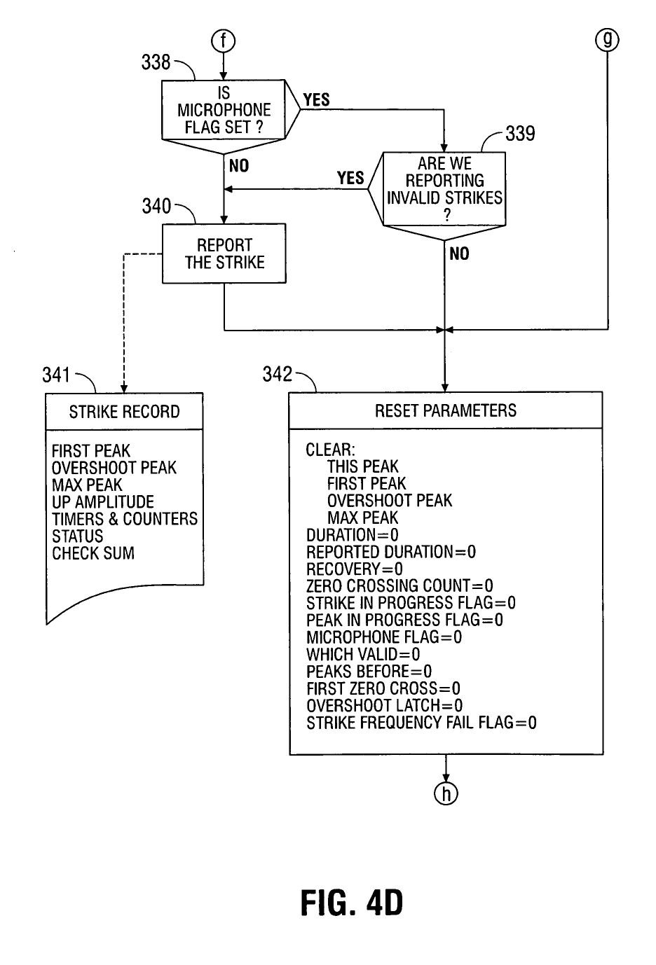

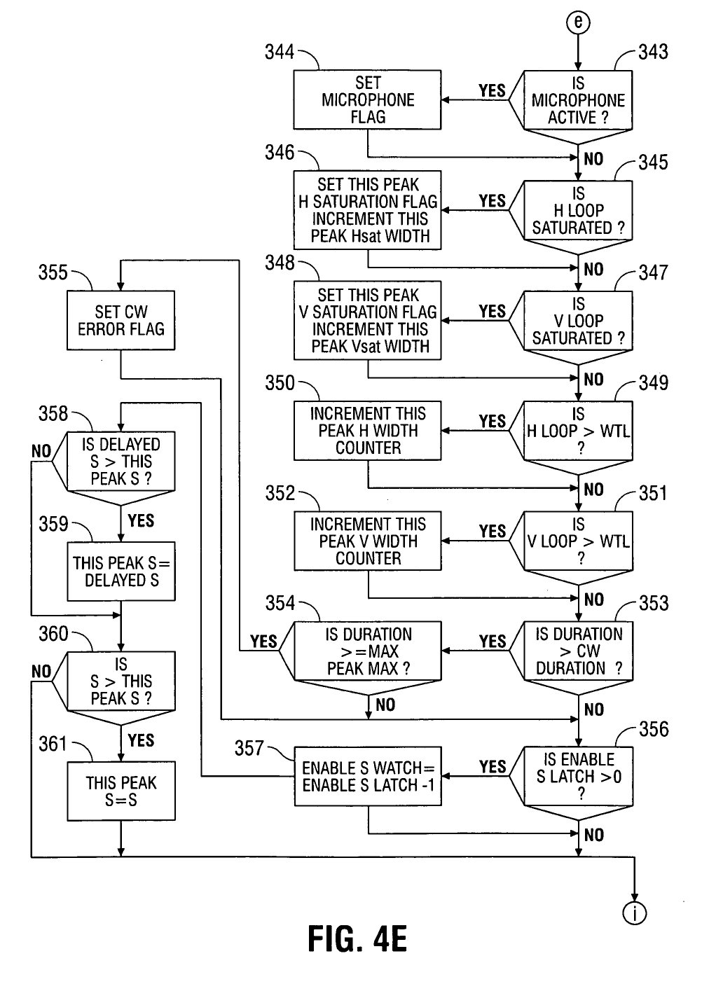

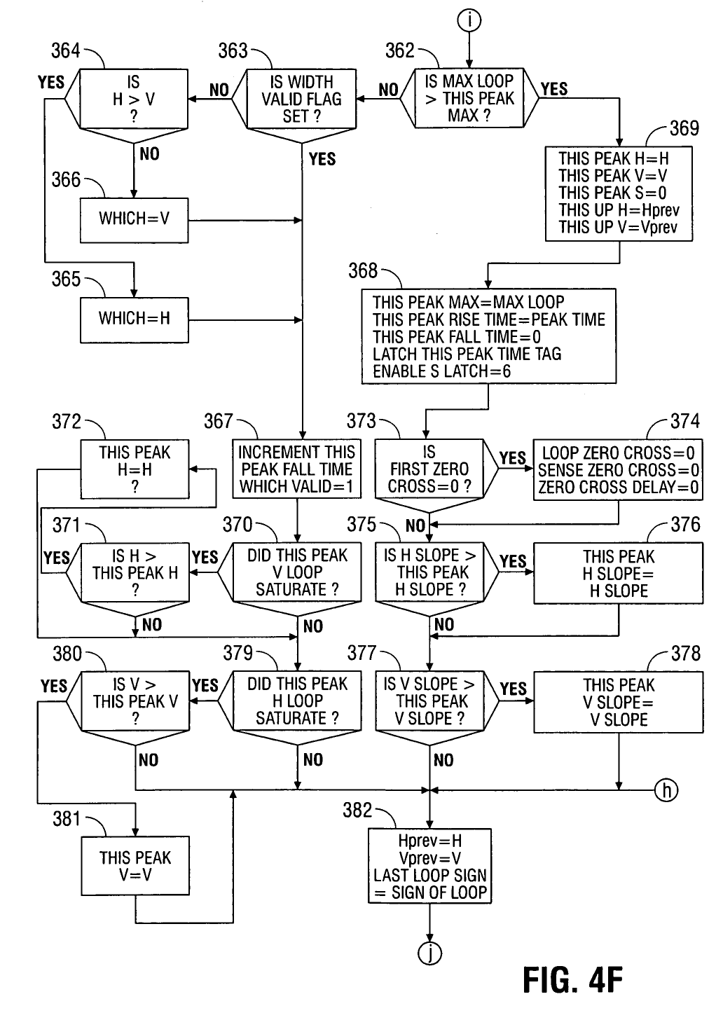

FIG. 2 is a flow chart 2000 of steps performed by the system 100 to use the filtered signal 118 or the non-filtered signal 120 in accordance with example embodiments of the invention. After the flow diagram starts (2005), the system 100 detects whether there is energy emitted by at least one lightning strike. The system 100 furthermore separates the detected lightning strike into a filtered signal 118 and a non-filtered signal 120. If there is no lightning strike, then the system 100 continues to monitor for a lightning strike (2010). If there is a lightning strike, a saturation detector 113 determines whether the filtered signal 118 is saturated (2015). If the filtered signal 118 is not saturated, the signal processor 105 uses the filtered signal 118 to calculate a signal width and generate a waveform (2035). From the waveform, a bearing and striking distance is calculated. The flowchart 2000 then continues to FIG. 4A, starting with whether the Which Valid flag is set (2050). This is further explained below with references to FIGS. 4A-4F.

However, if the filtered signal 118 is saturated, a comparator 115 using the non-filtered signal 120 determines (2020) whether the lightning strike is less than or equal to a predetermined lightning strike distance relative to the system 100. In this example, the predetermined lightning strike distance is 20 nmi. If the strike is greater than 20 nmi, the comparator 115 asserts a “0” flag (2040). The signal processor 105 then uses the filtered signal 118 to generate a waveform (2045). From the waveform, a bearing and striking distance is calculated. The flowchart 2000 then continues to FIG. 4A, starting with whether the Which Valid flag is set (2050).

If the lightning strike is less than or equal to 20 nmi, the comparator 115 asserts a “1” flag (2025). The signal processor 105 then uses the non-filtered signal 120 to generate a waveform (2030). The flowchart 2000 then continues to FIG. 4A, starting with whether the Which Valid flag is set (2050).

### Flash Mode

A flash is a series of strikes that occur within a very short period of time (up to about 1 second) at the same location. Flash mode provides a display of each flash after the individual lightning return strokes have been reassembled into flashes. Some enhancements of this display mode are described in the following sections.

### Colored Flashes

It would be desirable to provide a flash mode that is more useful than the monochrome display of dots or symbols previously used. Color is one method of enhancing this method of lightning display. There are many methods that might be used to assign the color to strikes including the age of a strike or the number of return strokes comprising the flash. Although these approaches may be useful they result in a mixing of colored flash indications that is difficult to interpret in any meaningful way.

To provide coloration of the flashes that can be quickly and easily interpreted to gain some meaningful understanding of the thunderstorm activity, the flashes are colored according to the cell that they would fall into. More specifically, the color of each flash comes from the cell mode hexagon that it falls into for the shortest range cell image that contains the strike. So for instance, a flash at 70 nmi would get its color from the 100 nmi cell mode hexagon that it falls into.

This method of selecting the color allows the pilot to see where the flashes are as well as where the most intense centers of thunderstorm activity are.

### Reduction of Radial Spread

It should be noted that a fairly simple extension of the colored flashes concept can provide tremendous improvements to the radial spread shown in the flash mode. If the color of the hexagonal cell for a given flash is black, then the flash is not displayed at all. In the preferred embodiment, black flashes would not even be transmitted to the display.

### Flash Clusters

The process of assembling return strokes into flashes helps to refine the location of the flash by combining the range and bearing estimates of each detected return stroke; however, it has the drawback of reducing the number of displayed events on the screen. In highly active regions of thunderstorm activity, the average number of strikes in a flash will increase, causing the more active regions to be minimized to some degree.

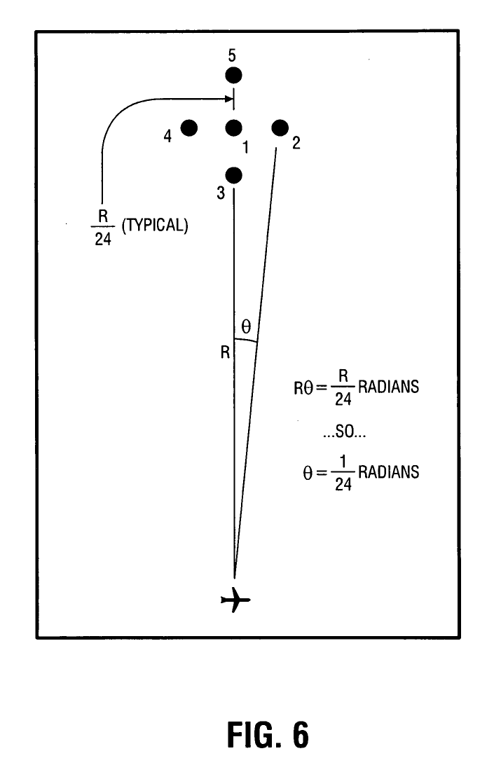

To resolve this without losing the benefits of flash assembly, each flash is drawn as a cluster of strikes. The number of strikes shown in the cluster will be equal to the weight (number of strikes) of the flash up to a maximum of five strikes. FIG. 6 shows the relationship between the first displayed strike and the second through fifth.

In practice, a separation between the initial strike and the additional strikes worked well as a function of range, because it is undesirable for the closer flash clusters to look as if they are widely separated when the range scale is decreased. It is also a logical choice since the range and bearing of the individual strikes can be measured more accurately at closer ranges. The factor selected in the preferred embodiment was range divided by 24. As shown in the figure above, this same distance was used between the first strike and all four of the additional strikes. Since the center is a measure of range and bearing from the host, it was necessary to relate R/24 to bearing. A reasonable estimate for the bearing offset can be obtained by setting the length of the arc (RΘ) to R/24. Solving for Θ results in one 24th of a radian. Therefore the position of each additional strike is found as follows:

| Position | Range | Bearing |
|---|---|---|
| 1 | Center Range | Center Bearing |
| 2 | Center Range | Center Bearing + 1/24 radian |
| 3 | 23/24 * Center Range | Center Bearing |
| 4 | Center Range | Center Bearing − 1/24 radian |
| 5 | 25/24 * Center Range | Center Bearing |

### Flash+Cell Mode

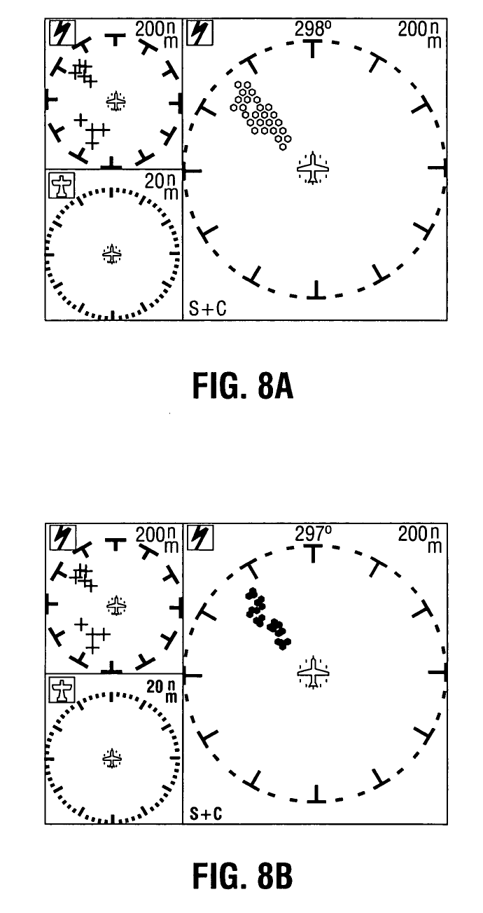

An extension of the cell mode and the flash mode is to combine the two. The flash mode provides the “raw” or discrete events, while the cell mode provides a more visually attractive, and more easily interpreted, image. In the preferred embodiment, this mode is implemented as a cell mode display with all flashes drawn as white dots. The flashes are blinked at a 0.5 Hz rate so that they are on for one second and off for one second. The sample images (FIG. 8A-8B) show the cell mode (left, large window) and the strikes overlaid on cell mode (right, large window).

### Lightning Weights and Regional Effects

Because lightning can be observed originating from and terminating at a specific location, it is frequently perceived as being a pin-point event. However, if lightning is considered to have a regional effect that extends for some distance around the actual event, it is possible to gain some understanding of the region of space that generated the strike. In other words, there is some region within which conditions were conducive to the build-up of static electric fields adequate to cause a lightning discharge. It is this region of unstable atmosphere that is of most importance and interest to a pilot. By combining the regional effects of numerous lightning return strokes, it is possible to build a complete image of the region of unstable atmosphere that is generating the lightning.

Single-station lightning detection systems depend upon the “typical” intensity of a lightning return stroke to estimate the distance to a detected lightning event. Since no two lightning strikes are the same, there is a natural variation in the strength of the generated field, which leads to variations in estimated range. These variations cause the estimated range to vary from the actual range, and are typically referred to as radial spread. There are many methods that can help to minimize radial spread, all of which could be applied in a system based upon the concepts discussed here.

Although variations in estimated range can be quite substantial, analysis of data collected by a single-station lightning detection system have shown that despite the variation in intensity of individual return strokes, it is likely that the estimated range for the lightning will be close to the actual range. This leads to a clustering of data at ranges representative of the region of atmosphere that is generating the lightning. By combining the regional effects of each individual return stroke to determine the weight of each element of a hexagonal grid, an image can be built that clearly shows the regions of atmospheric instability.

A lightning flash is assigned a weight that is equal to the number of strikes that comprise the flash. A flash is considered to have an effect for some range from the estimated location of the event. The weight of the event will be highest at the estimated location, and will fall off with range according to some distribution curve. Various distribution curves may be used; however, a sinusoidal distribution has been shown to produce pleasing results. The weight (or effect) of a flash at a given distance from its estimated location can be determined as follows:

$$WeightAtRange = Flash Weight \cdot [ ( cos ( 90 ° \cdot \frac{range}{MaxRange} ) \cdot ( 1 - offset ) ) + offset ]$$

### Where:

Flash Weight is the weight of the flash.

WeightAtRange is the effective weight or effect of a flash at a given range.

range is the range from the estimated flash location at which you want to determine the effect of the flash.

MaxRange is the maximum range at which the flash has an effect.

offset is the magnitude of the effect at MaxRange (i.e., offset 0.4 would indicate that the effect of the flash is 40% down at MaxRange).

When constructing a grid display, the effect of every flash is added to any element of the array that falls within the range of effect. As these effects are added to the elements of the array, an image representing the regions of activity is produced.

It is worth noting that the sinusoidal weighting produces a useful side-effect. Since cos 45°=0.71, two flashes separated from one another by MaxRange will have their greatest effect halfway between the two events. This makes sense since the region of activity is not greatest at a flash, but at the center of a cluster of flashes.

### Ranging of Very Close Strikes

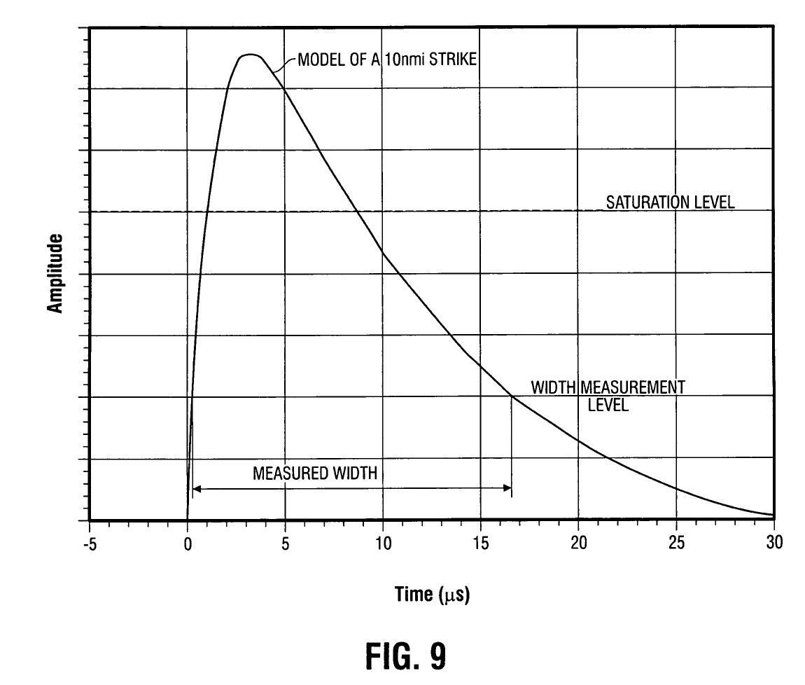

The received magnetic field waveform of lightning has a very fast rise time, and a somewhat slower fall time. The fall time of the waveform becomes somewhat more elongated as the distance to the strike gets closer than about 15 miles due to the addition of the intermediate field (see the waveform of a 10 nmi strike in FIG. 9). Therefore, the width of the initial peak of the lighting waveform gets wider the further down the waveform is measured.

Since all receivers have a finite dynamic range, there is typically a trade-off between the maximum detectable range, the resolution of the data, and the minimum detectable range. Lightning is especially challenging when trying to detect it at close range, because the signal is so large. To eliminate this problem the receiver having a FPGA could be designed to make a decision as to whether to use the filtered signal or the non-filtered signal. The FPGA may look at the non-filtered signal to determine how wide the signal is and/or how wide the saturated signal is, but the system does not use information from the non-filtered signal unless the filtered signal is saturated, and it is that qualification of the non-filtered signal that makes it desirable to use the non-filtered signal. A flow chart describing the decision making process is explained in FIG. 2. When the lightning signal saturates the receiver based on the filtered signal, it is not possible to use the peak amplitude of the filtered signal to estimate the range. Instead, the width of the pulse from the non-filtered signal is measured to estimate the range. The width is typically measured at a fixed level so that it can be related to the width of the standard lightning model at that level. The estimated range to the strike is the range where the model has the same width at the level used for the measurement. For example, FIG. 9 shows the model of a 10 nautical mile strike. If the measured width of a saturated strike is the same as the width shown in this example, then the range to the strike is 10 nautical miles.

In addition to modifying how the range is estimated, it is also necessary to modify how the bearing is calculated for a saturated signal, since the bearing is typically calculated as the arctangent of the ratio of the horizontal and vertical loop amplitudes at the peak of the strike. Since the ratio of the horizontal and vertical loop signals is the same throughout the waveform of a lightning strike, the bearing could be measured at any point on the waveform using the non-filtered signal. In practice, however, atmospheric reflections and other phenomena can cause the later portion of the waveform to have inconsistencies. To avoid these issues, the bearing should be measured on the rising edge of the initial waveform peak. To maximize resolution it is best to measure it as near the saturation point as practical. In some embodiments, the receiver signals are sampled and digitized.

The relation between the measured width of a lightning waveform and the equivalent amplitude is determined based on a table relating these two parameters. In fact, there are two different tables, for two different kinds of lightning strikes. There is a significant difference between the waveforms of cloud-to-ground lightning (C-G) and other forms of lightning (inter-cloud and cloud to air, non C-G). One aspect of that difference is that the fall time (and hence the pulse width) of non C-G lightning is significantly shorter than C-G lightning. Consequently, there is a different relation between pulse width and equivalent amplitude for C-G lightning and non C-G lightning. A further difference between the waveforms for C-G lighting and non C-G lightning is the ratio of peak amplitude to overshoot amplitude. In C-G lightning, the peak is typically some multiple (at least two or greater) of the overshoot peak, whereas in the non-C-G lightning the ratio is typically around unity. Furthermore, the width of non C-G lightning is usually shorter than the pulse width for C-G lightning. The ratio of peak and overshoot and the pulse width parameters of the waveform data that declares a pulse to be non-C-G lightning if the ratio of peak and overshoot is about unity and the pulse width is less than a threshold duration. For pulses categorized as C-G lightning, the C-G table to relate pulse width to equivalent amplitude whereas for other pulses (non-C-G lightning), the non C-G table is used.

### Audible Lightning Callouts

In commercial aircraft it is common for a crewmember to call out lightning that occurs nearby. With this in mind, it would be a useful feature for an airborne lightning detection system to call out nearby lightning events. A callout such as “Lightning! One O'clock” would provide the flight crew with immediate feedback of local conditions. The callouts would be limited to lightning detected within some range, for example 5 nautical miles. The range cutoff for audible callouts should be adequately small to prevent excessive nuisance alarms.

Since some storms can be very active, there should be some ability to limit the number of callouts. For instance, the system may limit the number of callouts provided within a certain period of time. If this threshold is exceeded, the callouts could be suppressed for a period of time. Audio suppression may also be done on a quadrant basis, where callouts for lightning occurring in a particular quadrant would be independently suppressed based upon the number/frequency of callouts due to that quadrant's activity. This would be helpful to assure that callouts from each active quadrant are heard before they are suppressed.

It should be noted that without the ability to accurately detect and map lightning at very close ranges this capability would not be practicable. With the previously described method of close-range detection and mapping, this idea becomes feasible.

### Regional Statistics

It is helpful to provide the user of lightning detection equipment statistical data regarding the thunderstorm activity that is being viewed. Prior art has typically chosen to provide strike rate statistics for the visible screen, without regard for the number of areas or regions of thunderstorm activity being displayed. One region may be much stronger than another, and one region may be diminishing while another is intensifying.

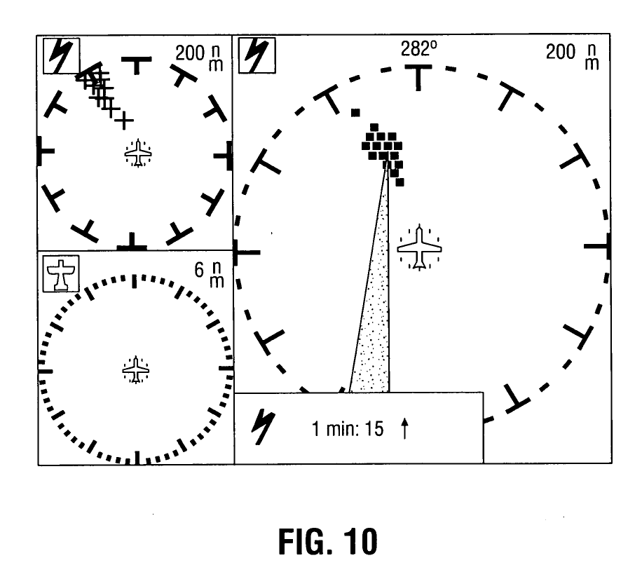

To improve upon the usefulness of the statistical data provided to the pilot, in one embodiment of the present invention the individual regions of thunderstorm activity may be identified and allows the pilot to step through the statistics for each region. An example of this method is shown in the large window of FIG. 10.

This image shows a single region with a strike rate of 15 strikes per minute. It also indicates with an up-arrow that the strike rate is increasing. It is important to note that additional statistics may be displayed such as the ratio of positive to negative strikes and the rate at which the ratio is changing. The processing to produce these statistics proceeds as follows. The data in the Cell Display Buffer 105f reveals the location of lightning activity and its relation to other locations of lightning activity. A threshold, such as the dim green index (2) is used. All adjacent cells were considered with activity above the index 2 to be in a single region. Thus, the border of any region is evidenced by an index of 2 or lower. A unique designation may be assigned for each region as well as a location for the region, such as the location of a cell with the highest activity in the region. The processor then determines a set of statistics for the region such as strike rate, strike rate trend (is the rate increasing or decreasing) and strike polarity. This data may then be provided to the display and displayed either unconditionally or subject to the operator selection. Referring to FIG. 1C, the strike processor 105a has access to the strike data which describes the waveform of each strike. One of the relevant parameters is the S amplitude. The polarity of this parameter defines the polarity of the strike. This data is carried forward in the Flash Assembly Queue 105b. The same data, i.e., strike polarity data is carried forward in the Flash Display Buffer 105e where the weight of the flash is the number of strikes in the flash. This data is used in computing regional statistics so strike rate, strike rate trend and strike polarity may be determined, computed and displayed.

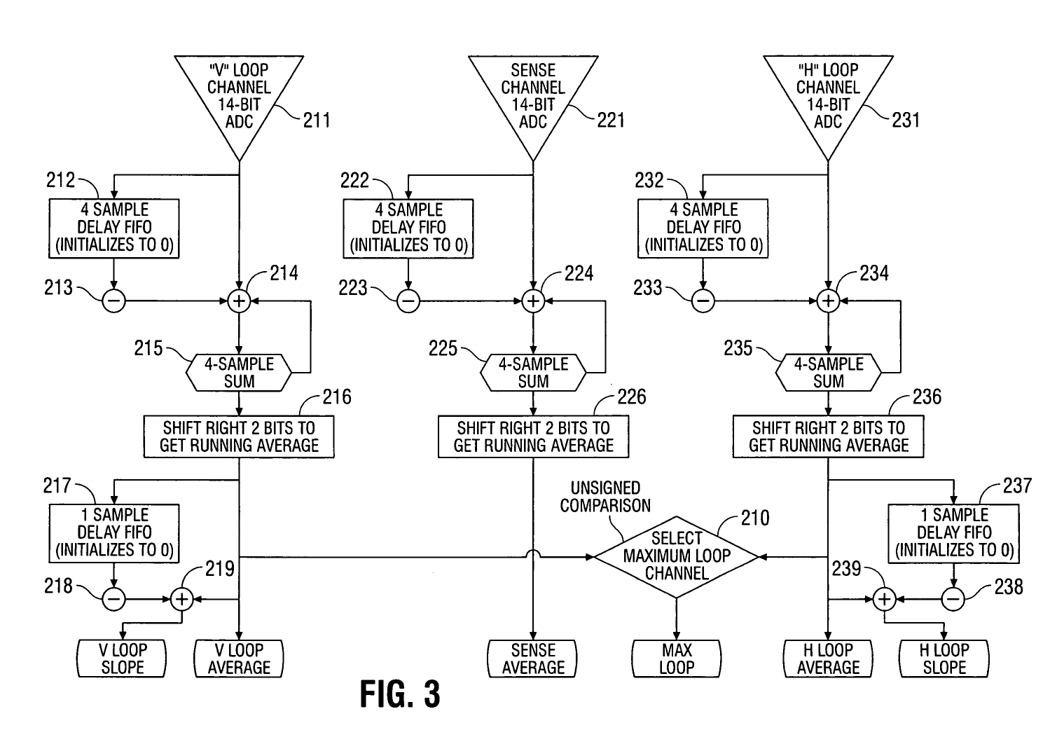

FIG. 3 is a block diagram of the A-D converter 104. As represented in FIG. 1A, the three-channel wide band receiver 102 provides three inputs to the A-D converter 104. These are provided as shown in FIG. 3 to a V loop channel ADC 211 (receiving one of the loop antenna inputs to the wide band receiver), a sense channel ADC 221 (receiving the electric field sensor input to the wide band receiver 102) and a H channel ADC 231 (receiving the other magnetic loop input). Each of the channels includes a four-sample delay FIFO (212, 222 and 232), adder (214, 224, 234) and sign changer (213, 223 and 233) to produce in the registers 215, 225 and 235 a four-sample sum. The four-sample sum is shifted right two bits (216, 226 and 236) to generate a running average of the most recent four samples. The output 226 is a sequence of samples representing a four-sample running average of the sense channel. Similar outputs 216 and 236 represent a running average of the V loop and H loop channels, respectively.

The H and the V channels also include a one-sample delay (217 and 237) adder and sign changer (218-219 and 238-239). The output of 219 and 239 represents the slope of the V channel and H channel, respectively. This is simply the difference (218) between the most recent running average and the immediately prior running average. Finally, the outputs of the shifters 216 and 236 are provided to the comparator 210 to select the maximum loop channel called Max Loop.

FIG. 3 illustrates how the six outputs of the ADC 104 are generated from its three inputs. Those six outputs are the V channel slope, the V channel running average, the sense channel (the S channel) running average, max loop, the running average of the H channel and the slope of the H channel.

The logic of the signal processor complex 105 is represented in part by the flow chart of FIGS. 4A-4G. The logic of the flow chart responds to the inputs provided by the ADC 104, a set of flags, variables and constants and the values in several programmable registers. The flags, variables and constants are defined as follows:

H=H loop average.

V=V loop average.

S=Sense channel average.

Max Loop=Greater of H or V, (Unsigned comparison)

Loop=The loop channel that is to be used to detect the zero crossing. When the Which Valid flag is not set, Loop is the same as Max Loop. When the Which Valid flag is set, Loop is the channel that the Which flag points at.

H Slope=H−Hprev.

V Slope=V−Vprev.;

Hprev=The value of H during the previous sample, H[n−1].

Vprev=The value of V during the previous sample, V[n−1]

Last Loop Sign=Sign of Loop during the previous sample.

Delayed S=If S[N] is the current sample then Delayed S is S[N−6]. In other words, the S sample is 6 samples old.

Which flag=When a strike is active, this indicates which loop channel caused the highest peak. This is latched during the first peak on the first sample that does not cause a new highest peak.

Which Valid flag=Set when the Which flag has been set.

First Peak=This is the H, V, and S amplitudes at the peak of First Peak. This may not be the literal first peak of the waveform if the literal first peak is more than 25% below the amplitude of a subsequent peak. Initial peaks that are more than 25% below the amplitude of a subsequent peak are considered leader currents.

Overshoot Peak=The H, V, and S amplitudes of the highest amplitude sample detected during the overshoot. The overshoot begins following the first zero crossing after the first peak, and continues until the second zero crossing

This Peak=The H, V, and S amplitudes of the highest amplitude sample detected during the waveform peak that is currently being received. Later, a decision will be made about whether to save This Peak as the First Peak or Overshoot Peak.

Max Peak=This is the H, V, and S amplitude of the sample that caused the highest Loop amplitude during the strike.

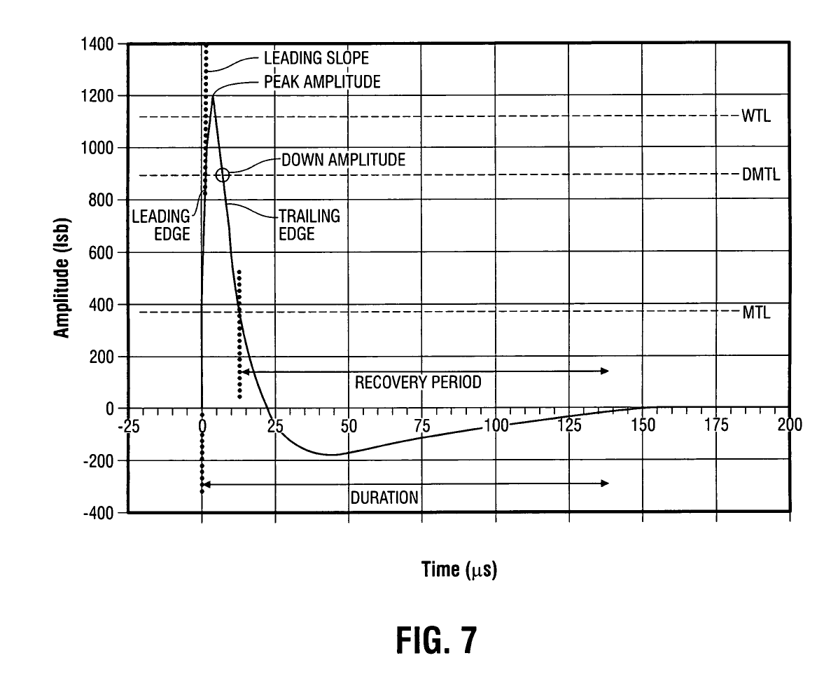

Duration=Number of samples comprising the strike, includes the first sample to exceed MTL and all following samples until the end of the strike. (See FIG. 7.)

Recovery=Count of number of samples below ZTL as illustrated in FIG. 7. This is used to determine if the strike is finished.

Peak Time=Number of samples that loop has been above ZTL.

Strike in Progress=Flag that indicates that the system is currently in the process of receiving a strike.

Peak in Progress=Flag that indicates that the system is in the process of receiving a peak of the waveform.

CW Error flag=Flag used to report conditions that may impair strike detector performance. This flag should be made available for the software (of the programmable processor) to read. This flag can only be cleared by the software.

Microphone flag=Indicates that the microphone was active at some time during reception of the strike. A latched copy of this flag should be made available for the software to read. The copy should not be cleared until specifically cleared by the software.

SenseZeroCross=Flag that indicates whether the sense channel has fallen back below ZTL.

LoopZeroCross=Flag that indicates whether Max Loop has fallen back to ZTL.

FirstZeroCross=Non-zero after the first zero crossing.

ZeroCrossingCount=The count of the number of zero crossings detected.

ZeroCrossDelay=The number of samples between the time that the Sense channel and Max Loop fall below ZTL. This is an unsigned value and it does not depend upon one or the other falling below ZTL first.

Peaks Before=The number of peaks before First Peak that were greater than the largest peak before it, and which were less than four times the amplitude of the largest peak preceding it. Note that Peaks Before is reset whenever a peak is found that is four times or more the amplitude of the highest peak before it.

Enable S Latch=This is a counter that counts down the number of samples following an update of This Max Peak that was checked in the Delayed S for a maximum peak. This compensates for the phase mismatch between the loops channels and the S channel.

The values which are obtained from programmable registers in the processor complex 105 are defined as follows:

Recovery Period=The number of samples below MTL required for a strike to be declared complete. FIG. 7 is illustrative.

CW Duration=Longest strike duration that does not cause the noise error flag to be set.

Saturation Level=At or about this level a loop channel is said to be saturated.

MTL=Minimum Trigger Level Strike processing will begin if Max Loop exceeds MTL (FIG. 7). This level should be set low enough to detect smaller peaks that may precede the primary peak, since such smaller peaks may invalidate the strike.

RTL=Report Trigger Level. Once a strike is finished, it will not be reported unless the First Peak Max amplitude that was latched during this strike is greater than RTL.

WTL (Width Trigger Level)=level where pulse width is measured (see FIG. 7).

ZTL (Zero Trigger Level)=When Max Loop is below ZTL the Peak Time counter is cleared.

Finally, definitions of a number of peak related variables are defined as follows:

H=The maximum value of H during the peak

V=The maximum value of V during the peak.

S=The maximum value of S during the peak.

Max=The maximum amplitude seen on either the H or V channel during the peak.

H Width=The number of samples that H was above WTL.

V Width=The number of samples that V was above WTL.

H Saturation Flag=Did H saturate during this peak?

V Saturation Flag=Did V saturate during this peak?

Hsat Width=The number of samples that the H channel was saturated.

Vsat Width=The number of samples that the V channel was saturated.

Rise Time=Number of samples above MTL up to and including the highest amplitude sample.

Fall Time=Number of samples following the highest amplitude sample up to the zero crossing. This count should include the first sample below zero. If a zero crossing is not detected, then this will be the number of samples from the peak to the end of the strike.

Up H=The H amplitude of the sample immediately preceding the highest amplitude sample.

Up V=The V amplitude of the sample immediately preceding the highest amplitude sample.

Up S=The S amplitude of the sample immediately preceding the highest amplitude sample.

Max H Slope=The maximum value of H Slope detected during the peak.

Max V Slope=The maximum value of V Slope detected during the peak.

One function of signal processor complex 105 is to filter out invalid strikes from the valid signals using the six inputs from the ADC, as well as the values in the programmable registers.

For the strikes which are not filtered out, the signal processor 105 also determines a plurality of parameters to characterize the respective waveforms. As will be described these parameters are passed on for further processing.

For each apparently valid strike the signal processor complex 105 generates the following data for further processing:

Time tag: with a resolution measured in microseconds.

First Peak—H amplitude and up amplitude.

First Peak—V amplitude and up amplitude.

First Peak—S amplitude and Max Loop.

Overshoot Peak—H amplitude and Max Slope of First Peak.

Overshoot Peak—V amplitude and Max Slope of First Peak.

Overshoot Peak—S amplitude and Max Loop amplitude.

Max Peak—H amplitude and MTL.

Max Peak—V amplitude.

Max Peak—S amplitude and Max Loop.

First Peak—H width (# of saturated samples) and V width (# of saturated samples).

First Peak—H saturation flag, V saturation flag, H width (# of samples >WTL),

V width (# of samples>WTL).

Timer Data—First Peak rise time (from ZTL to peak), First Peak fall time, total strike duration.

Status—Valid flag, H CW Freq. fail flag, Microphone flag, V CW Freq. fail flag, CW error flag, Peaks before count (First Peak), zero crossing count (First Peak), Zero crossing delay (# of samples between S and loop going below ZTL).

FIGS. 4A-4F shows a flow diagram of the strike detection logic of signal processor complex 105. Among other functions this logic develops much of the foregoing data. Each sample of the three channels will cause one transition through this logic. The following paragraphs narrate the flow. The amplitude comparisons in the flow diagram are unsigned comparisons, thus the maximum loop channel is the loop channel with the greatest amplitude regardless of sign. When the system determines if the maximum loop channel is greater than WTL, the system determines if the unsigned amplitude of the maximum loop channel is greater than WTL, and so on.

The following constants are set up in software programmable registers to permit fine-tuning of the strike detector performance without firmware changes.
MTL—Minimum Trigger Level.
RTL—Report Trigger Level.
WTL—Width Trigger Level.
ZTL—Zero Trigger Level.
CW duration—Strike detection lasting longer than this generates a noise error.
Recovery period—Signal must remain below MTL for this period to finish a strike.
Saturation Level—At or above this level, a loop channel is said to be saturated.

The values used in these registers are determined empirically and some of the values may also be dynamic (i.e., arranged to be changed under predetermined conditions).

The first thing that happens following receipt of a sample is to initialize Loop. If the WhichValid flag is not set (301), the Loop is simply set to Max Loop (305). Otherwise the Which flag is used to determine which channel to set to (302-304). The Which flag indicates which of the two loop channels has a higher amplitude for this strike. For example, the processor complex 105 receives information on the presence of continuous wave energy (CW), i.e., the CW error flag. On detection of the CW error flag, the level of MTL and ZTL is raised by a small amount in an attempt to defeat the noise. In the absence of setting of the CW error flag, the level of MTL and ZTL may be lowered by a small amount. Adjusting the amounts by which MTL and ZTL are changed and the time delays in applying the changes allows noise to be combated.

The sign of Loop is then used to determine if a zero crossing has occurred (306). A zero crossing is detected whenever Loop changes sign (307) while the WhichValid flag is set. If a zero crossing is detected, then the Peak Time is reset to zero (309). If a peak was in progress prior to this zero crossing (310), then This Peak is inspected to determine if it should be used as Max Peak (311, 312). Any This Peak that has a higher Max than Max Peak will be used as the new Max Peak. If This Peak has a Max that is more than four times the Max of First Peak, then This Peak will be used as First Peak (314, 324). Since First Peak is cleared to zero after a strike is finished, then the first peak to be detected will automatically become the initial First Peak. The Zero Crossing Count is reset to zero every time First Peak is updated. If the Zero Crossing Count is one, then This Peak is used to update Overshoot Peak. Since Zero Crossing Count is reset to zero after First Peak is updated, the very next peak to be detected will be the overshoot peak of the Zero Crossing Count will have been incremented to 1.

The Peak Time, Duration and Recovery counters (313) are incremented at this point.

If Max Loop is less than or equal to the Zero trigger Level (ZTL) (325), then Peak Time is reset to zero (326). ZTL is set to some level below MTL to provide a more accurate measure of the rise time. Not using only the zero crossing to reset Peak Time also avoids excessively large rise times caused by a continuous low amplitude signal that precedes the initial return stroke.

A check is made whether This Peak is saturated (316). If so, Hsat Width of This Peak is compared to Hsat of the First Peak (315). If larger, This Peak becomes First Peak (324). If the peak did saturate but Hsat of This Peak is not greater than Hsat width of First Peak then the Vsat width is compared to the Vsat width of First Peak 317. If the Vsat width is greater than This Peak becomes First Peak (324), otherwise the flow is directed to check if This Peak Max>First Peak Max (318). If so, This Peak becomes the First Peak and Peaks Before is incremented (319). If not, then the Overshoot Latch is checked to see if it is clear (320). If it is, then This Peak is declared to be Overshoot Peak and the Overshoot Latch is set (321). If the Overshoot Latch is not clear, then the ZeroCrossingCount is incremented and This Peak is cleared (322). Thereafter, Peak in Progress is cleared, First Zero Count is set and Duration becomes Reported Duration (323).

If the Max Loop is greater than the Minimum Trigger Level (MTL), then the Strike in Progress flag is set and the Peak in Progress flag is set (332, 333).

At this point, if there is not a strike in progress (334), then all of the basic parameters are reset to defaults and the loop is finished (335). If there is a strike in progress, then the recovery period is evaluated. If the recovery period has expired, then the strike is finished. Only strikes that have a First Peak Max that is greater than the Report Trigger Level (RTL) will be reported (337). If the Microphone flag is set (338), then the strike will only be reported if invalid strike reporting has been enabled (339). If the strike is to be reported, then a report is generated (340, 341). Referring to FIG. 1A reveals that the microphone switch 103 is another input to the receiver 102. The status of the microphone is a signal which is sampled and passed on to the signal processor complex 105. The switch merely repeats the status of the microphone, either at rest or in use. This allows the processor complex 105 to record this as a parameter of the strike signal. Since use of the microphone can reflect noise, the system discards all strike waveforms which are received at a time when the microphone is active.

If there is a strike in progress (334) and the recovery period has not been elapsed (336), then the strike is continuing. If the microphone input is asserted, then the Microphone flag is set (343, 344). If the strike Duration is greater than CW Duration, then the CW Error flag is set (353, 354, 355). If the H loop has saturated (345), then the H Saturation flag is set (346), and if the V loop has saturated (347), then the V Saturated flag is set (348).

Since the sense channel is not necessarily in-phase with the two-loop channels, the system may need to look for the peak of the sense channel near the peak of the loop channels (356), but it may not occur at exactly the same time. If the Enable S Latch counter is greater than zero, then the system is looking for the peak of the sense channel. The Enable S Latch counter is decremented (357) and then if the current S amplitude is greater than This Peak S (360), then This Peak S is updated with the current S amplitude (361). If the S amplitude that is six samples old is greater than This Peak S (358), then This Peak S is updated with the value of the S amplitude that is six samples old (359). This process repeats for six cycles as the Enable S Latch counter decrements. When all is done, This Peak S will contain the maximum S amplitude that occurred within five samples after and six samples before the peak of the loop channels.

Next the Max Loop is checked to see if it is greater than This Peak Max (362). If it is, then This Peak H and This Peak V are set to the current H and V values, respectively (369). This Peak S is set to zero. This Peak Max is set to Max Loop, This Peak Rise Time is updated with the value of Peak Time, This Peak Fall Time is zeroed, This Peak Time Tag is latched, and the Enable S Latch counter is initialized to six. This Up H and This Up V are set to the H and V value of the previous sample (369).

Thereafter, a determination is made as to whether First Zero Cross is clear (373). If it is then LoopZeroCross, SenseZeroCross and ZeroCrossDelay are cleared (374). If not, or after completing function 374, a determination is made as to whether H Slope is >This Peak H Slope (375). If it is not, a determination is made as to whether V Slope>This Peak V Slope (377). If either H Slope or V Slope is greater then This Peak Slope, it is reset to H or V Slope (376, 378).

Thereafter, a determination is made as to whether First Zero Cross is clear (373). If it is, then LoopZeroCross, SenseZeroCross and ZeroCrossDelay are cleared (374). If not, or after completing function 374, a determination is made as to whether H Slope is >This Peak H Slope (375). If it is not, a determination is made as to whether V Slope>This Peak V Slope (377). If either H Slope or V Slope is greater, then This Peak Slope is reset to H or V Slope (376, 378).

If Max Loop is not greater than This Peak Max, then the Which Valid flag is checked (363). If it is not set, then Which is set to point at whichever loop channel currently has the greater magnitude (364-366).

Next, This Peak Fall Time is incremented (367), and Which Valid is set.

If one of the two loops saturates (345, 347), then This Peak saturation flag is set and the relevant width measure is incremented (346, 348).

If H loop is greater than WTL (349), then This Peak H Width is incremented (350). If V loop is greater than WTL (351), then This Peak V Width is incremented (352).

At this point, Duration is compared to CW Duration (353), if greater then a determination is made as to whether Duration>=Max Peak Max (354). If it is, the CW Error Flag is set (355). If not, a determination is made as to whether the Enable S Latch is greater than zero. If it is, then the count is decremented (357). A determination is then made as to whether Delayed S>This Peak S (358). If it is, then This Peak S becomes Delayed S (359). In either event, a determination is made as to whether S>This Peak S (360). If so, This Peak S becomes S (361).

A determination is made (370) as to whether This Peak Loop V is saturated. A check is made to determine whether H>This Peak H (371). If so, This Peak H becomes H (372). If either determination is in the negative, then a check is made as to whether This Peak H loop is saturated (379). If it did, then a check is made as to whether V>This Peak V. If so, This Peak V becomes V.

Before completing the cycle, the current H, V and sign data is stored as the previous data (382) and the process repeated.

FIG. 4F shows the loop carrier wave detector logic. This logic is duplicated for the two-loop channels. X Loop refers to the loop channel amplitude for the channel that the logic is applied to. The logic runs in parallel with and independent of the logic of FIGS. 4A-4F except that the strike frequency fail flag is reported in the strike record, and is cleared at the end of strike detection. The following variables are used in this logic:
Period: Number of samples in one-half cycle of a CW signal. This is the number of samples between the point that the waveform exceeds ZTL on opposite sides of a zero crossing.
Cutoff: This is the number of samples in half a period of the highest valid frequency. Fewer samples than this is an indication that the frequency is too high.
Bad Frequency Count: Number of times the half-period measurement of the frequency indicated that the frequency is too high.
Fail Limit: If Bad Frequency Count is above this it will set the Frequency Fail Flag.
Frequency Fail Flag: Indicates that high frequency carrier wave is present.
Strike Frequency Fail Flag: Indicates that a high frequency carrier wave was detected at some time during the current strike in progress.

The signal processor complex 105 determines for each strike, values for First Peak, Overshoot Peak, Max Peak, Up Amplitude, Timer and Counters Status and a Check Sum. With this information, the further processing effects three major functions. In the first place, it continues the filtering of invalid strikes. In addition, it determines, for each strike which passes the various tests, an estimated bearing and range. If the strike does not exhibit any saturation in either loop, the range is determined from the Max Peak. Also absent saturation, bearing is determined from the ratio of the H and V Peaks. If one of the channels does saturate during the strike, then neither of these methods can be used. In the event of saturation, the relevant pulse width (H or V), depending on which channel became saturated, is used. The width value allows a determination to be made of an equivalent amplitude. Based on the equivalent amplitude, a range can be calculated for the strike. Recall that the relation between pulse width and equivalent amplitude depends on the categorization of the lightning as C-G or non C-G. The tests used to distinguish C-G lightning from non C-G lightning is described above and how the result of the test is used to select the appropriate table so that the proper equivalent amplitude can be determined from the pulse width. The presence of saturation also makes it impossible to use the bearing determination as a ratio of the H and V peaks. Rather, in lieu of the peak amplitude for the bearing determination, the up amplitude for both loops is extracted and the ratio establishes the desired bearing. Having determined range and bearing for each strike, the processor can then determine the weight to be given to different regions in the relevant space based on the presence and distribution to the strikes. The strikes, located with their range and bearing (and time of receipt) will then be incorporated into a flash, alone if there are no related strikes, otherwise melded with other strikes which are adjacent in time and space.

### Strike Rejections

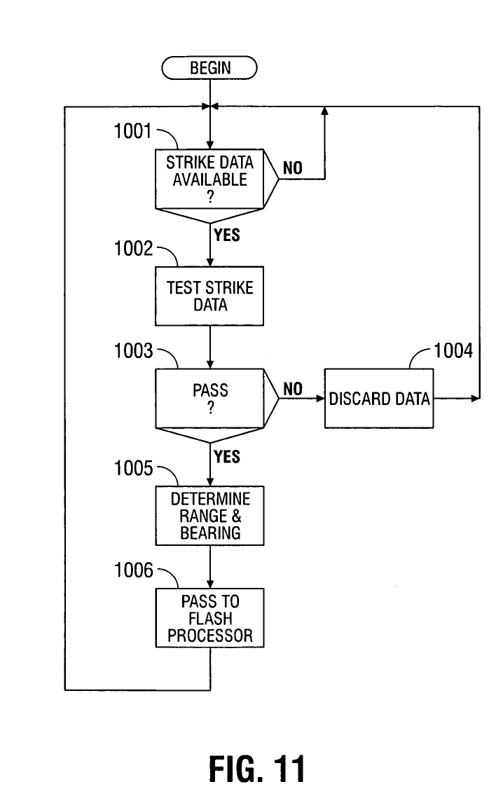

FIG. 11 shows the strike rejection functions of the processor complex 105. The initial function 1001 determines if strike data is available. If not, the processor loops waiting for new strike data. If there is new strike data, function 1002 applies a number of tests to the strike data.

The software in the processor complex 105 uses the following criteria:

A strike which has a rise time which is less than a determined amount is an indication of a man-made signal, atmospheric reflection or some other interference. In a system which used a clock rate of 33 MHz and a sample rate of 33/16 Mhz, the rise time requirement was less than about 21 samples (i.e., less than about 10-12 microseconds).

Valid strikes show a correlation between the signals generated by the loop and sense antennas. The processor complex 105 has available to it Sense Loop and Max Loop. The criteria used is that the amplitude of the sense channel show at least three quarters of the Max Loop amplitude, but no more than three times the Max Loop amplitude.

The next criterion is that the parameter “Peaks Before” must be zero. There may not be any peaks more than one quarter of the maximum measured peak prior to the Max Peak.

The magnitude of the Overshoot Peak of S must be less than or equal to 110% of the magnitude of the First Peak S.

The Max Peak Loop magnitude must be less than or equal to 110% of the First Peak Max Loop magnitude.

The strike duration must be less than a predetermined time. In an embodiment where the sample rare was 2.0625 M amples per sec., the allowable duration must be less than 2000 samples.

Zero plus delay between the sense and the max loop channel is checked. The time duration cross (for example, measured in terms of samples) between the max loop channel reaching zero compared to a sense channel magnitude reaching zero must be no more than a predetermined amount.

There should be no continuous wave frequency measured during the lightning active time, which is more than 57 kHz above the ZTL.

Finally, the check sum 1003 is to verify the data in the record is current. If not, the record is discarded 1004. Although this set of strike rejection criteria fulfills the goals for providing a useful display to the pilot, it is apparent that those skilled in the art will be able to vary some of the parameters of one or more of these criteria or add to the criteria to suit particular situations within the spirit of the invention. Step 1005 determines range bearing using known techniques and outputs determined range and bearing to step 1006 which passes the data to the flash processor 105b . . . d.

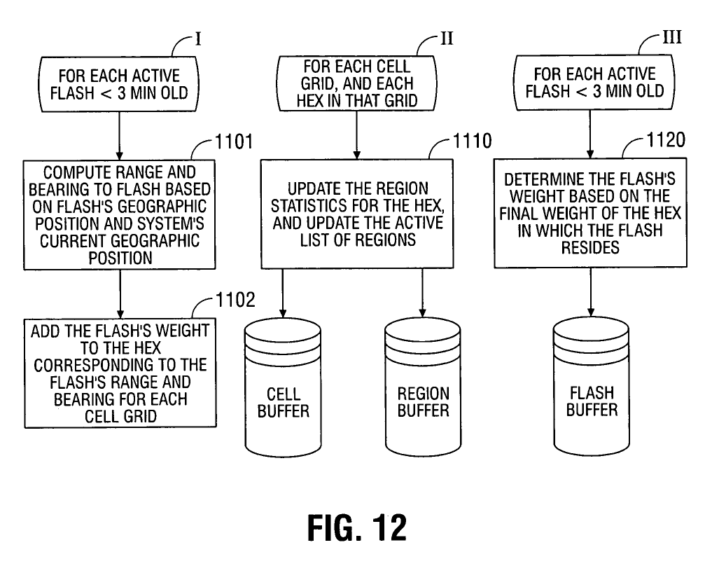

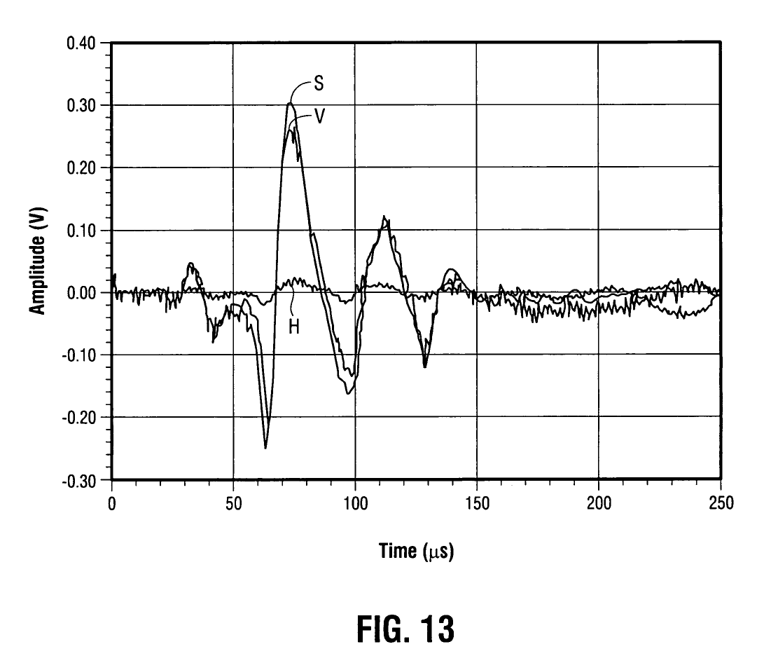

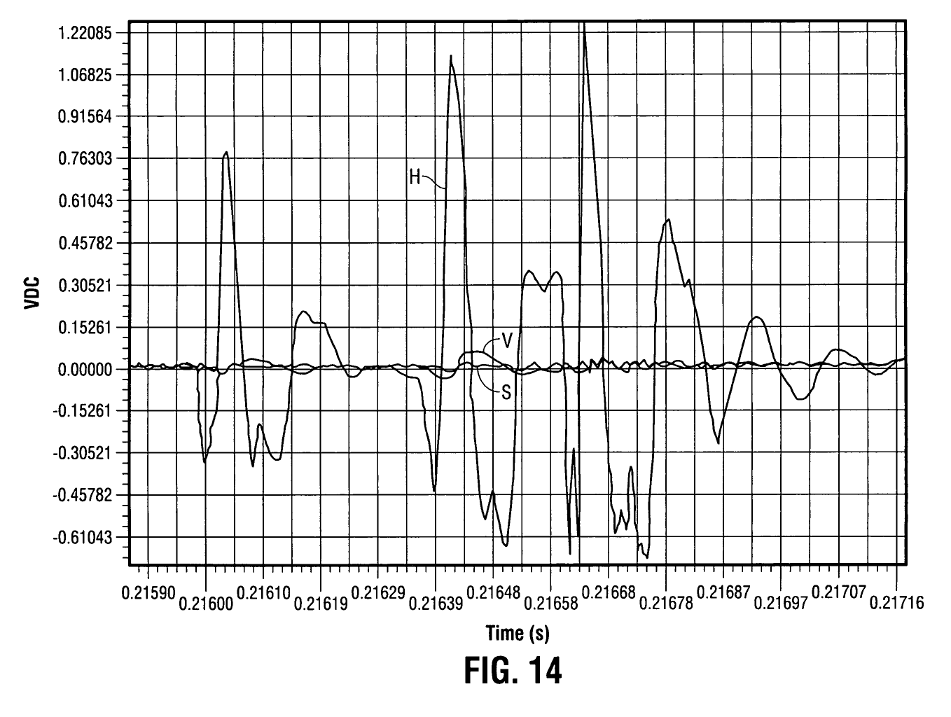

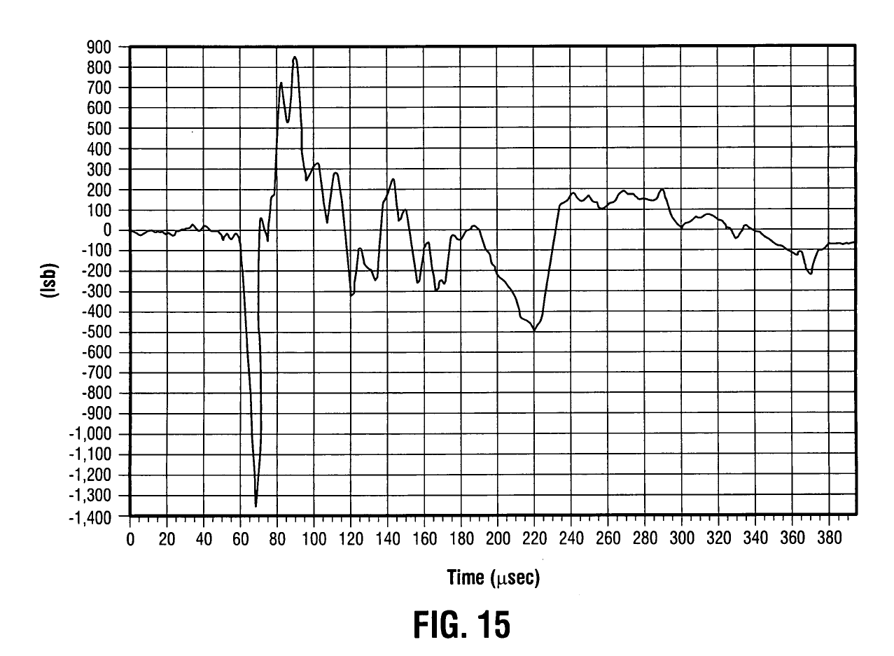

Further processing carried out by the processor complex 105 is illustrated in the flow diagram of FIG. 12. FIG. 12 shows three different threads, two (I and III) show functions performed for each active flash which is less than 3 minutes in age, and the third (II) for each location in the arrays associated with the displays. In one embodiment of the invention flashes older than 3 minutes are not displayed.

The processor complex 105 stores an array of cells for each different range scale that may be displayed (see Cell Display Buffer, 105e in FIG. 1b). In one embodiment, the operator may select from five different range scales, one displaying a 200 nmi max range, another with a 100 nmi max range, a third with a 50 nmi max range, a fourth with a 25 nmi max range, and a fifth 10 nmi range. The display for each range scale has a predetermined number of hexagonal elements to show the selected region, typically each range scale has the same number of elements; in one embodiment there are approximately 1900 cells per range scale. Thus, the processor stores five arrays, each with approximately 1900 locations. The data stored in these locations will now be described.

The first thread I has two functions. In function 1101 the processor computes the range and bearing to the flash based on the location of the flash and the current location of the vehicle supporting the equipment. Recall that function 1005 (FIG. 11) had determined the range and bearing of the strike when the data was accepted by the processor complex 105. The range and bearing determined at that time (when function 1005 is performed) is used, in connection with flash processing to determine the geographic position of the flash based on the geographic position of the system when the strikes making up the flash was detected. Function 1101 determines a current range and bearing to the flash based on the geographic position of the flash and a more current position of the system. Given the flash's location and its weight (number of strikes), the processor determines (1102) which of the elements in each array are affected by the flash and the amount of the effect. When this process is repeated for each active flash then each of the arrays has had its data made current and is available for display.

Given the weight for each hexagonal element, it is then necessary to develop an index value which is used to select the color for that hex element. There is a different table for each different range scale (200 nmi, 100 nmi, 50 nmi, 25 nmi and 10 nmi). For a given range scale an array is developed which stores a color index for each cell of that array. The color index is obtained from the table related to the range scale. The five tables are reproduced below:

200nmi table:

| | | | | | | | | | | | | | | | | | |
|---|---|---|---|---|---|---|---|---|---|---|---|---|---|---|---|---|---|
| // | 0 | 1 | 2 | 3 | 4 | 5 | 6 | 7 | 8 | 9 | A | B | C | D | E | F | |
| | 0, | 1, | 1, | 1, | 1, | 2, | 2, | 3, | 3, | 4, | 4, | 5, | 5, | 6, | 6, | 6, | // 0 |
| | 6, | 7, | 7, | 7, | 7, | 7, | 7, | 7, | 7, | 7, | 7, | 7, | 7, | 7, | 7, | 7, | // 1 |
| | 7, | 7, | 7, | 7, | 7, | 7, | 7, | 7, | 7, | 7, | 7, | 7, | 7, | 7, | 7, | 7, | // 2 |
| | 7, | 7, | 7, | 7, | 7, | 7, | 7, | 7, | 7, | 7, | 7, | 7, | 7, | 7, | 7, | 7, | // 3 |
| | 7, | 7, | 7, | 7, | 7, | 7, | 7, | 7, | 7, | 7, | 7, | 7, | 7, | 7, | 7, | 7, | // 4 |
| | 7, | 7, | 7, | 7, | 7, | 7, | 7, | 7, | 7, | 7, | 7, | 7, | 7, | 7, | 7, | 7, | // 5 |
| | 7, | 7, | 7, | 7, | 7, | 7, | 7, | 7, | 7, | 7, | 7, | 7, | 7, | 7, | 7, | 7, | // 6 |
| | 7, | 7, | 7, | 7, | 7, | 7, | 7, | 7, | 7, | 7, | 7, | 7, | 7, | 7, | 7, | 7, | // 7 |
| | 7, | 7, | 7, | 7, | 7, | 7, | 7, | 7, | 7, | 7, | 7, | 7, | 7, | 7, | 7, | 7, | // 8 |
| | 7, | 7, | 7, | 7, | 7, | 7, | 7, | 7, | 7, | 7, | 7, | 7, | 7, | 7, | 7, | 7, | // 9 |
| | 7, | 7, | 7, | 7, | 7, | 7, | 7, | 7, | 7, | 7, | 7, | 7, | 7, | 7, | 7, | 7, | // A |
| | 7, | 7, | 7, | 7, | 7, | 7, | 7, | 7, | 7, | 7, | 7, | 7, | 7, | 7, | 7, | 7, | // B |
| | 7, | 7, | 7, | 7, | 7, | 7, | 7, | 7, | 7, | 7, | 7, | 7, | 7, | 7, | 7, | 7, | // C |
| | 7, | 7, | 7, | 7, | 7, | 7, | 7, | 7, | 7, | 7, | 7, | 7, | 7, | 7, | 7, | 7, | // D |
| | 7, | 7, | 7, | 7, | 7, | 7, | 7, | 7, | 7, | 7, | 7, | 7, | 7, | 7, | 7, | 7, | // E |
| | 7, | 7, | 7, | 7, | 7, | 7, | 7, | 7, | 7, | 7, | 7, | 7, | 7, | 7, | 7, | 8, | // F |

100nmi table:

| | | | | | | | | | | | | | | | | | |
|---|---|---|---|---|---|---|---|---|---|---|---|---|---|---|---|---|---|
| // | 0 | 1 | 2 | 3 | 4 | 5 | 6 | 7 | 8 | 9 | A | B | C | D | E | F | |
| | 0, | 1, | 1, | 1, | 2, | 2, | 3, | 3, | 4, | 4, | 5, | 5, | 6, | 6, | 6, | 6, | // 0 |
| | 6, | 7, | 7, | 7, | 7, | 7, | 7, | 7, | 7, | 7, | 7, | 7, | 7, | 7, | 7, | 7, | // 1 |
| | 7, | 7, | 7, | 7, | 7, | 7, | 7, | 7, | 7, | 7, | 7, | 7, | 7, | 7, | 7, | 7, | // 2 |
| | 7, | 7, | 7, | 7, | 7, | 7, | 7, | 7, | 7, | 7, | 7, | 7, | 7, | 7, | 7, | 7, | // 3 |
| | 7, | 7, | 7, | 7, | 7, | 7, | 7, | 7, | 7, | 7, | 7, | 7, | 7, | 7, | 7, | 7, | // 4 |
| | 7, | 7, | 7, | 7, | 7, | 7, | 7, | 7, | 7, | 7, | 7, | 7, | 7, | 7, | 7, | 7, | // 5 |
| | 7, | 7, | 7, | 7, | 7, | 7, | 7, | 7, | 7, | 7, | 7, | 7, | 7, | 7, | 7, | 7, | // 6 |
| | 7, | 7, | 7, | 7, | 7, | 7, | 7, | 7, | 7, | 7, | 7, | 7, | 7, | 7, | 7, | 7, | // 7 |
| | 7, | 7, | 7, | 7, | 7, | 7, | 7, | 7, | 7, | 7, | 7, | 7, | 7, | 7, | 7, | 7, | // 8 |
| | 7, | 7, | 7, | 7, | 7, | 7, | 7, | 7, | 7, | 7, | 7, | 7, | 7, | 7, | 7, | 7, | // 9 |
| | 7, | 7, | 7, | 7, | 7, | 7, | 7, | 7, | 7, | 7, | 7, | 7, | 7, | 7, | 7, | 7, | // A |
| | 7, | 7, | 7, | 7, | 7, | 7, | 7, | 7, | 7, | 7, | 7, | 7, | 7, | 7, | 7, | 7, | // B |
| | 7, | 7, | 7, | 7, | 7, | 7, | 7, | 7, | 7, | 7, | 7, | 7, | 7, | 7, | 7, | 7, | // C |
| | 7, | 7, | 7, | 7, | 7, | 7, | 7, | 7, | 7, | 7, | 7, | 7, | 7, | 7, | 7, | 7, | // D |
| | 7, | 7, | 7, | 7, | 7, | 7, | 7, | 7, | 7, | 7, | 7, | 7, | 7, | 7, | 7, | 7, | // E |
| | 7, | 7, | 7, | 7, | 7, | 7, | 7, | 7, | 7, | 7, | 7, | 7, | 7, | 7, | 7, | 8, | // F |

50nmi table:

| | | | | | | | | | | | | | | | | | |
|---|---|---|---|---|---|---|---|---|---|---|---|---|---|---|---|---|---|
| // | 0 | 1 | 2 | 3 | 4 | 5 | 6 | 7 | 8 | 9 | A | B | C | D | E | F | |
| | 0, | 1, | 2, | 3, | 3, | 4, | 4, | 4, | 5, | 5, | 5, | 5, | 6, | 6, | 6, | 6, | // 0 |
| | 6, | 7, | 7, | 7, | 7, | 7, | 7, | 7, | 7, | 7, | 7, | 7, | 7, | 7, | 7, | 7, | // 1 |
| | 7, | 7, | 7, | 7, | 7, | 7, | 7, | 7, | 7, | 7, | 7, | 7, | 7, | 7, | 7, | 7, | // 2 |
| | 7, | 7, | 7, | 7, | 7, | 7, | 7, | 7, | 7, | 7, | 7, | 7, | 7, | 7, | 7, | 7, | // 3 |
| | 7, | 7, | 7, | 7, | 7, | 7, | 7, | 7, | 7, | 7, | 7, | 7, | 7, | 7, | 7, | 7, | // 4 |
| | 7, | 7, | 7, | 7, | 7, | 7, | 7, | 7, | 7, | 7, | 7, | 7, | 7, | 7, | 7, | 7, | // 5 |
| | 7, | 7, | 7, | 7, | 7, | 7, | 7, | 7, | 7, | 7, | 7, | 7, | 7, | 7, | 7, | 7, | // 6 |
| | 7, | 7, | 7, | 7, | 7, | 7, | 7, | 7, | 7, | 7, | 7, | 7, | 7, | 7, | 7, | 7, | // 7 |
| | 7, | 7, | 7, | 7, | 7, | 7, | 7, | 7, | 7, | 7, | 7, | 7, | 7, | 7, | 7, | 7, | // 8 |
| | 7, | 7, | 7, | 7, | 7, | 7, | 7, | 7, | 7, | 7, | 7, | 7, | 7, | 7, | 7, | 7, | // 9 |
| | 7, | 7, | 7, | 7, | 7, | 7, | 7, | 7, | 7, | 7, | 7, | 7, | 7, | 7, | 7, | 7, | // A |
| | 7, | 7, | 7, | 7, | 7, | 7, | 7, | 7, | 7, | 7, | 7, | 7, | 7, | 7, | 7, | 7, | // B |
| | 7, | 7, | 7, | 7, | 7, | 7, | 7, | 7, | 7, | 7, | 7, | 7, | 7, | 7, | 7, | 7, | // C |
| | 7, | 7, | 7, | 7, | 7, | 7, | 7, | 7, | 7, | 7, | 7, | 7, | 7, | 7, | 7, | 7, | // D |
| | 7, | 7, | 7, | 7, | 7, | 7, | 7, | 7, | 7, | 7, | 7, | 7, | 7, | 7, | 7, | 7, | // E |
| | 7, | 7, | 7, | 7, | 7, | 7, | 7, | 7, | 7, | 7, | 7, | 7, | 7, | 7, | 7, | 8, | // F |

25nmi table:

| | | | | | | | | | | | | | | | | | |
|---|---|---|---|---|---|---|---|---|---|---|---|---|---|---|---|---|---|
| // | 0 | 1 | 2 | 3 | 4 | 5 | 6 | 7 | 8 | 9 | A | B | C | D | E | F | |
| | 0, | 1, | 2, | 3, | 3, | 4, | 4, | 4, | 5, | 5, | 5, | 5, | 6, | 6, | 6, | 6, | // 0 |
| | 6, | 7, | 7, | 7, | 7, | 7, | 7, | 7, | 7, | 7, | 7, | 7, | 7, | 7, | 7, | 7, | // 1 |
| | 7, | 7, | 7, | 7, | 7, | 7, | 7, | 7, | 7, | 7, | 7, | 7, | 7, | 7, | 7, | 7, | // 2 |
| | 7, | 7, | 7, | 7, | 7, | 7, | 7, | 7, | 7, | 7, | 7, | 7, | 7, | 7, | 7, | 7, | // 3 |
| | 7, | 7, | 7, | 7, | 7, | 7, | 7, | 7, | 7, | 7, | 7, | 7, | 7, | 7, | 7, | 7, | // 4 |
| | 7, | 7, | 7, | 7, | 7, | 7, | 7, | 7, | 7, | 7, | 7, | 7, | 7, | 7, | 7, | 7, | // 5 |
| | 7, | 7, | 7, | 7, | 7, | 7, | 7, | 7, | 7, | 7, | 7, | 7, | 7, | 7, | 7, | 7, | // 6 |
| | 7, | 7, | 7, | 7, | 7, | 7, | 7, | 7, | 7, | 7, | 7, | 7, | 7, | 7, | 7, | 7, | // 7 |
| | 7, | 7, | 7, | 7, | 7, | 7, | 7, | 7, | 7, | 7, | 7, | 7, | 7, | 7, | 7, | 7, | // 8 |
| | 7, | 7, | 7, | 7, | 7, | 7, | 7, | 7, | 7, | 7, | 7, | 7, | 7, | 7, | 7, | 7, | // 9 |
| | 7, | 7, | 7, | 7, | 7, | 7, | 7, | 7, | 7, | 7, | 7, | 7, | 7, | 7, | 7, | 7, | // A |
| | 7, | 7, | 7, | 7, | 7, | 7, | 7, | 7, | 7, | 7, | 7, | 7, | 7, | 7, | 7, | 7, | // B |
| | 7, | 7, | 7, | 7, | 7, | 7, | 7, | 7, | 7, | 7, | 7, | 7, | 7, | 7, | 7, | 7, | // C |
| | 7, | 7, | 7, | 7, | 7, | 7, | 7, | 7, | 7, | 7, | 7, | 7, | 7, | 7, | 7, | 7, | // D |
| | 7, | 7, | 7, | 7, | 7, | 7, | 7, | 7, | 7, | 7, | 7, | 7, | 7, | 7, | 7, | 7, | // E |
| | 7, | 7, | 7, | 7, | 7, | 7, | 7, | 7, | 7, | 7, | 7, | 7, | 7, | 7, | 7, | 8, | // F |

10nmi table:

| | | | | | | | | | | | | | | | | | |
|---|---|---|---|---|---|---|---|---|---|---|---|---|---|---|---|---|---|
| // | 0 | 1 | 2 | 3 | 4 | 5 | 6 | 7 | 8 | 9 | A | B | C | D | E | F | |
| | 0, | 1, | 2, | 3, | 3, | 4, | 4, | 4, | 5, | 5, | 5, | 5, | 6, | 6, | 6, | 6, | // 0 |
| | 6, | 7, | 7, | 7, | 7, | 7, | 7, | 7, | 7, | 7, | 7, | 7, | 7, | 7, | 7, | 7, | // 1 |
| | 7, | 7, | 7, | 7, | 7, | 7, | 7, | 7, | 7, | 7, | 7, | 7, | 7, | 7, | 7, | 7, | // 2 |
| | 7, | 7, | 7, | 7, | 7, | 7, | 7, | 7, | 7, | 7, | 7, | 7, | 7, | 7, | 7, | 7, | // 3 |
| | 7, | 7, | 7, | 7, | 7, | 7, | 7, | 7, | 7, | 7, | 7, | 7, | 7, | 7, | 7, | 7, | // 4 |
| | 7, | 7, | 7, | 7, | 7, | 7, | 7, | 7, | 7, | 7, | 7, | 7, | 7, | 7, | 7, | 7, | // 5 |
| | 7, | 7, | 7, | 7, | 7, | 7, | 7, | 7, | 7, | 7, | 7, | 7, | 7, | 7, | 7, | 7, | // 6 |
| | 7, | 7, | 7, | 7, | 7, | 7, | 7, | 7, | 7, | 7, | 7, | 7, | 7, | 7, | 7, | 7, | // 7 |
| | 7, | 7, | 7, | 7, | 7, | 7, | 7, | 7, | 7, | 7, | 7, | 7, | 7, | 7, | 7, | 7, | // 8 |
| | 7, | 7, | 7, | 7, | 7, | 7, | 7, | 7, | 7, | 7, | 7, | 7, | 7, | 7, | 7, | 7, | // 9 |
| | 7, | 7, | 7, | 7, | 7, | 7, | 7, | 7, | 7, | 7, | 7, | 7, | 7, | 7, | 7, | 7, | // A |
| | 7, | 7, | 7, | 7, | 7, | 7, | 7, | 7, | 7, | 7, | 7, | 7, | 7, | 7, | 7, | 7, | // B |
| | 7, | 7, | 7, | 7, | 7, | 7, | 7, | 7, | 7, | 7, | 7, | 7, | 7, | 7, | 7, | 7, | // C |
| | 7, | 7, | 7, | 7, | 7, | 7, | 7, | 7, | 7, | 7, | 7, | 7, | 7, | 7, | 7, | 7, | // D |
| | 7, | 7, | 7, | 7, | 7, | 7, | 7, | 7, | 7, | 7, | 7, | 7, | 7, | 7, | 7, | 7, | // E |
| | 7, | 7, | 7, | 7, | 7, | 7, | 7, | 7, | 7, | 7, | 7, | 7, | 7, | 7, | 7, | 8, | // F |

Each table stores 256 color index values. The weight for any cell is the index into the table. Applying the index to the table selects one value in the table which is the color index corresponding to that particular weight and range scale. The data is stored in the cell display buffer.

As previously indicated, the data in the Cell Display Buffer 105f reveals the location of lightning activity and its relation to other locations of lightning activity. A threshold, such as the dim green index (2) may be selected. The system considers all adjacent cells with activity above the index 2 to be in a single region. Thus, the border of any region is evidenced by an index of 2 or lower. The system provides a unique designation for each region as well as a location for the region, such as the location of a cell with the highest activity in the region. The processor then determines (1110) a set of statistics for the region such as strike rate, strike rate trend (is the rate increasing or decreasing) and strike polarity. This data may then be provided to the display and displayed either unconditionally or subject to the operator selection.

The third thread (III) provides data for flash display. It may be desirable for the flash display to be in color. Thread III produces the necessary data. In particular, for each flash found in the flash buffer, the system determines the weight (activity) for the corresponding hexagonal element in which the flash is found 120. This index is written to the Flash Buffer 105e so that on a Flash display each flash may take on that color indicated by the weight found in the corresponding Cell buffer 105f.

Finally when de-emphasizing the activity of lower weights to allow the user to focus in on higher weight activity, an alert to the user may be desirable to lower the weight activity if it is sufficiently close in. To this end, the Cell Display Buffers for the 200, 100 and 50 nmi range scales are associated with an alert message (typically to be presented visually on a display but in some cases this may be augmented or replaced by another mode of alert) to the effect that there is moderate activity on a 25 nmi scale or smaller.

While the foregoing specification describes specific characteristics of a preferred embodiment of the invention, those skilled in the art will understand that the scope of the invention is to be understood by the claims attached hereto and should not be limited by the specific characteristics which are described by way of example and not by way of limitation.

What is claimed is:

1. A system for detecting lightning activity comprising:
a receiver configured to detect energy emitted by at least one lightning strike and separate the at least one lightning strike to a filtered signal and a non-filtered signal;
at least one saturation detector configured to determine if the filtered signal is saturated prior to the filtered signal being filtered; and
in response to the filtered signal being saturated, a processor configured to process the non-filtered signal from the receiver, estimate locations of the detected at least one lightning strike relative to the system, determine a cumulative effect of the at least one lightning strike spaced in distance and time, and generate display signals to illustrate the cumulative effect with respect to a grid.

2. The system of claim 1 wherein the saturation detector determines the filtered signal to be saturated based on the detected lightning strike being less than or equal to a predetermined lightning strike distance relative to the system.

3. The system of claim 1 wherein the processor is further configured to process the filtered signal from the receiver, in response to the filtered signal being non-saturated.

4. The system of claim 1 wherein the processor configured to process the non-filtered signal includes a width measurement based on a waveform to determine a range.

5. The system of claim 1 wherein the processor is further configured to process the filtered signal including converting a width measurement based on a waveform to determine a range.

6. The system of claim 3 wherein the saturation detector determines the filtered signal to be non-saturated based on the detected lightning strike being greater than a predetermined lightning strike distance relative to the system.

7. The system of claim 1 wherein the receiver includes:
at least a pair of loop channels, data received from the loop channel is used to calculate a range; and
at least one sense antenna associated with at least one sense channel, the at least one sense antenna configured to detect the energy emitted by the at least one lightning strike.

8. The system of claim 1 wherein the receiver is at least a one channel receiver.

9. The system of claim 1 is located on an aircraft.

10. The system of claim 1 wherein the grid comprises an array of hexagonal elements.

11. The system of claim 1 wherein the display signals illustrate the cumulative effect within a selectable display region and wherein each hexagonal element in an array of hexagonal elements is assigned a color based on an intensity of the determined cumulative effect.

12. The system of claim 11 wherein the color assigned to each of the hexagonal elements is based on the intensity of the cumulative effect and a selected range scale of a related display.

13. The system of claim 11 wherein the colors range from dark to light to illustrate different intensities, wherein the higher intensities are assigned to lighter colors.

14. The system of claim 1 further including an alarm system configured to provide an alert when a lightning strike is detected to be within a predetermined lightning strike distance relative to the system.

15. The system of claim 14 wherein the alert is an audible, visual, or any combination thereof.

16. The system of claim 14 wherein the alert identifies a range and bearing.

17. The system of claim 14 wherein the predetermined distance relative to the system is about 25 nautical miles (nmi).

18. The system of claim 1 wherein the processor is further configured to identify different regions based on locations of contiguous groups of hexagonal elements having an assigned color lighter than a predetermined color, generate statistical information of lightning activity in the different regions, and exhibit the display signals from the statistical information.

19. The system of claim 18 wherein the statistical information includes at least one of a strike rate, strike trend, and strike polarity.

20. The system of claim 1 wherein the processor determines a range of selected lightning strikes based on a time duration of the processed non-filtered signal waveform.

21. The system of claim 1 further including an operator control configured to select an overlay display mode in which the generated display signals illustrate the cumulative effect within a display region overlaid with locations of flashes.

22. The system of claim 1 wherein the receiver having a plurality of channels, each of the plurality of channels coupled to the at least one saturation detector, the at least one saturation detector is further configured to retain at least one prior sample.

23. The system of claim 22 wherein the processor is further configured to determine a bearing to a strike based on the retained sample.

24. The system of claim 7 wherein the processor determines strike range based on a waveform width in a loop channel of the filtered signal which saturate and waveform amplitude in another loop channel not exhibiting saturation.

25. The system of claim 7 wherein the processor determines strike range based on a waveform width in a loop channel of the non-filtered signal and waveform amplitude in another loop channel not exhibiting saturation.

26. The system of claim 7 wherein the processor determines strike range based on waveform width in loop channels of the filtered signal when both of the loop channels exhibit saturation.

27. A method for detecting lightning activity comprising the steps of:
detecting electromagnetic energy emitted by at least one lightning strike;
separating the at least one lightning strike to a filtered signal and a non-filtered signal;
determining if the filtered signal is saturated prior to the filtered signal being filtered;
in response to the filtered signal being saturated, processing the non-filtered signal for estimating locations of the at least one lightning strike relative to the system and for determining a cumulative effect of the at least one lightning strike spaced in distance and time; and
generating display signals to illustrate the cumulative effect with respect to a grid.

28. The method of claim 27 wherein in response to the filtered signal being saturated includes determining the detected lightning strike to be less than or equal to a predetermined lightning strike distance relative to the system.

29. The method of claim 27 further including processing the filtered signal, in response to the filtered signal being non-saturated.

30. The method of claim 29 wherein processing the filtered signal includes measuring a width of a waveform for determining a range.

31. The method of claim 30 wherein processing the filtered signal includes the detected lightning strike being greater than a predetermined lightning strike distance relative to the system.

32. The method of claim 27 wherein processing the non-filtered signal includes measuring a width based on a waveform for determining a range.

33. The method of claim 27 further including:
receiving data from at least one pair of loop channels for calculating a range using a receiver; and
detecting the energy emitted by the at least one lightning strike using at least one sense antenna, the sense antenna associating with at least one sense channel.

34. The method of claim 33 wherein the receiver is at least a one channel receiver.

35. The method of claim 27 wherein the grid comprises an array of hexagonal elements.

36. The method of claim 27 wherein the display signals illustrating the cumulative effect within a selectable display region and wherein for each hexagonal element in an array of hexagonal elements, assigning a color based on an intensity of the determined cumulative effect.

37. The method of claim 36 wherein assigning the color to each of the hexagonal elements is based on the intensity of the cumulative effect and a selected range scale of a related display.

38. The method of claim 36 wherein the colors ranging from dark to light for illustrating the different intensities and higher intensities are assigned to lighter colors.

39. The method of claim 27 further including generating an alert for lightning detected within a predetermined distance dependent on a selected display scale.

40. The method of claim 39 wherein the alert is an audible, visual, or any combination thereof.

41. The method of claim 27 further including identifying different regions based on locating contiguous groups of hexagonal elements having an assigned color lighter than a predetermined color, generating statistical information of lightning activity in the different regions, and displaying the generated display signals from statistical information.

42. The method of claim 41 wherein the statistical information includes at least one of a strike rate, strike trend, and strike polarity.

43. The method of claim 27 further including determining a range of selected lightning strikes based on a time duration of the processed non-filtered signal waveform.

44. The method of claim 27 further including providing an operator control to select an overlay display mode in which the generated display signals illustrate the cumulative effect within the display region overlaid with locations of flashes.

45. The method of claim 27 further including:
maintaining a plural, time displaced sample in each of a plurality of channels;
detecting a saturation for each of the plurality of channels; and
retaining at least one prior sample for each plurality of channels, in response to detecting the saturation.

46. The method of claim 45 wherein processing the non-filtered signal includes determining a strike based on the retained sample.

47. The method of claim 33 further including determining a strike range based on a waveform width in the at least one pair of loop channels of the filtered signal which saturate and waveform amplitude in another loop channel not exhibiting saturation.

48. The method of claim 33 further including determining a strike range based on a waveform width in the at least one pair of loop channels of the non-filtered signal and waveform amplitude on another loop channel not exhibiting saturation.

49. The method of claim 33 further including determining a strike range based on a waveform width in the at least one pair of loop channels of the filtered signal when both of the loop channels exhibit saturation.
